(19) United States
(12) Patent Application Publication
(10) Pub. No.: US 2026/0290671 A1
(43) Pub. Date: Sep. 24, 2026

(54) SYSTEMS AND METHODS FOR TOPOGRAPHIC MAPPING TO DESIGN MAGNETIC CORES

(71) Applicant: UT-Battelle, LLC, Oak Ridge, TN (US)

(72) Inventors: Emrullah Aydin, Knoxville, TN (US); Omer C. Onar, Knoxville, TN (US); Burak Ozpineci, Knoxville, TN (US)

(73) Assignee: UT-Battelle, LLC, Oak Ridge, TN (US)

(21) Appl. No.: 19/467,370

(22) Filed: Feb. 2, 2026

Related U.S. Application Data
(60) Provisional application No. 63/773,896, filed on Mar. 18, 2025.

(51) Int. Cl. H01F 27/24; B60L 53/122; G06F 30/20; H01F 27/22; H01F 41/02; H02J 50/10; H02J 105/37

(52) U.S. Cl. CPC H01F 27/24; B60L 53/122; G06F 30/20; H01F 27/22; H01F 41/0206; H02J 50/10; H02J 2105/37

(57) ABSTRACT

System and methods for providing a magnetic field. The methods comprise: supplying AC power to an electromagnetic coil assembly comprising at least one coil and a magnetic core; creating the magnetic field by the electromagnetic coil assembly; and using the magnetic core to increase the magnetic field in the electromagnetic coil assembly. The magnetic core has a variable thickness which increases in areas of relatively higher magnetic flux density and decreases in areas of relatively lower magnetic flux density.

### CROSS-REFERENCE TO RELATED APPLICATIONS

The present applications claims the benefit of and priority to U.S. Provisional Patent Application No. 63/773,896 which was filed on Mar. 18, 2025. The content of this U.S. Provisional Application is incorporated herein by reference in its entirety.

The present application concerns technology such as that disclosed in International Patent Publication No. WO2020/142621A2. The content of this International Patent Publication is incorporated herein by reference in its entirety.

### STATEMENT REGARDING FEDERALLY SPONSORED RESEARCH AND DEVELOPMENT

This invention was made with government support under Contract No. DE-AC05-00OR22725 awarded by the U.S. Department of Energy. The government has certain rights in this invention.

### BACKGROUND

### Description of the Related Art

Wireless power transfer (WPT) systems are safe and convenient methods for charging electric vehicle (EV) batteries. The power density of WPT systems has been increasing by using different coil and core geometries. Using magnetic core materials significantly decreases the reluctance of the magnetic flux path and helps increase magnetic coupling. However, core materials increase the weight and cost of a WPT system.

### SUMMARY

The present disclosure concerns implementing systems and methods for providing a magnetic field. The methods comprise: supplying AC power to an electromagnetic coil assembly comprising at least one coil and a magnetic core; creating the magnetic field by the electromagnetic coil assembly; and using the magnetic core to increase the magnetic field in the electromagnetic coil assembly, wherein the magnetic core has a variable thickness which increases in areas of relatively higher magnetic flux density and decreases in areas of relatively lower magnetic flux density.

The present disclosure also concerns a system comprising: a power source configured to supply alternating current; an electromagnetic coil assembly comprising at least one coil configured to create a magnetic field when the alternating current passes therethrough and a magnetic core configured to increase the magnetic coupling. The magnetic core has a variable thickness which increases in areas of relatively higher magnetic flux density and decreases in areas of relatively lower magnetic flux density.

The present disclosure also concerns implementing systems and methods for providing a cooling system for a structure. The methods comprise cooling the structure using a thermal interface having a variable thickness. The variable thickness increases in areas of relatively higher temperature and decreases in areas of relatively lower temperature.

The present disclosure further concerns a polyphase wireless power transfer system for wirelessly providing high-frequency AC power to an electric vehicle. The system comprises: an off-board transmitter comprising a primary coupler configured to wirelessly transmit the high-frequency AC power (the primary coupler comprising a plurality of primary-side coils backed by a primary-side core); and an on-board receiver comprising a secondary coupler configured to receive the high-frequency AC power when the primary coupler and the secondary coupler are disposed adjacent to each other and spaced apart by a gap (the secondary coupler comprising either a single secondary-side coil or a plurality of secondary-side coils backed by a secondary-side core). The plurality of secondary-side coils are configured to induce into the secondary-side core a spatially-dependent magnetic flux density distribution that rotates around an axis orthogonal to the plurality of secondary-side magnetic coils. The secondary-side core has a variable thickness that varies in a plane orthogonal to the axis like a linear combination of instances of the spatially-dependent magnetic flux density distribution. While the polyphase wireless power transfer coil is an example case here, the variable thickness geometry is applicable to single-phase wireless power transfer systems as well.

### BRIEF DESCRIPTION OF THE DRAWINGS

The present solution will be described with reference to the following drawing figures, in which like numerals represent like items throughout the figures.

FIG. 1 provides an illustration of a limped structure of a polyphase WPT system.

FIG. 2 provides a three-dimensional model of a polyphase wireless power transfer design.

FIG. 3 shows a magnetic flux density distribution on the secondary side core.

FIGS. 4A-4C (collectively referred to as “FIG. 4”) show the flux density distribution at different phase angles and their contour plat map drawings.

FIG. 5 provides an illustration showing that the contour plat map drawings for each case may be combined to create a three-dimensional model.

FIG. 6 provides an illustration showing a final (summed) contour plot map drawings and the corresponding three-dimensional structure.

FIGS. 7A-7E (collectively referred to as “FIG. 7”) provides illustrations of different core shapes. FIG. 7A shows a square core. FIG. 7B shows a round magnetic core. FIG. 7C shows a double-layer rectangular magnetic core. FIG. 7D shows a double-layer flower magnetic core. FIG. 7E shows a topographic mapping (or ATOM) magnetic core.

FIGS. 8A-8C (collectively referred to as “FIG. 8”) show half-models for different core shapes. FIG. 8A shows a half-model for a double-layer rectangular magnetic core. FIG. 8B shows a half model for a double-layer flower magnetic core. FIG. 8C shows a half-model for a topographic mapping (or ATOM) magnetic core.

FIG. 9 provides a graph showing a comparison of core loss and volume for different core designs.

FIG. 10 provides a graph showing the variation in Mₐₓ due the misalignment on both axes for the round magnetic core design.

FIG. 11 provides a graph showing the variation in Mₐₓ due the misalignment on both axes for the topographic mapping (or ATOM) magnetic core design.

FIG. 12 provides a graph showing the magnetic flux density at different points for the round magnetic core design.

FIG. 13 provides a graph showing the magnetic flux density at different points for the topographic mapping (or ATOM) magnetic core design.

FIG. 14 provides a flow diagram of an illustrative method for fabricating a topographic mapping (or ATOM) magnetic core.

FIG. 15 provides a diagram showing a system implementing the present solution.

FIG. 16A provides an illustration showing the relationship between the α-axis, β-axis and y-axis and coil placement. FIGS. 16B and 16C show examples of an α-mode and β-mode, respectively. FIGS. 16A-16C are collectively referred to as FIG. 16.

FIG. 17A provides an illustration showing a possible architecture for the primary coupler of FIG. 15. FIG. 17B shows an example of an α-mode for a double payer coils assembly shown in FIG. 17A. FIG. 17B shows an example of a β-mode for a double payer coils assembly shown in FIG. 17C. FIGS. 17A-17C are collectively referred to as FIG. 17.

FIG. 18A-18C provide illustrations showing the secondary coupler of FIG. 15. FIG. 18A provides a top view of the secondary coupler. FIG. 18B provides a perspective view of the topographic mapping (or ATOM) magnetic core of the secondary coupler. FIG. 18C provides a cross-section view of the topographic mapping (or ATOM) magnetic core taken along line B of FIG. 18.

FIG. 19 provides a flow diagram of an illustrative method for providing a magnetic field.

FIG. 20 provides a block diagram of an illustrative architecture for the load of FIG. 15.

FIG. 21 provides a block diagram of an illustrative architecture for a computing device.

FIG. 22 provides an illustration showing a temperature distribution of an ATOM core design.

FIG. 23 provides an illustration showing an illustrative cooling system.

### DETAILED DESCRIPTION

The term “bipolar” used herein refers to a flux produced by one coil has a natural return path through its twin. For example, if the current direction through phase A+ produces a flux in the positive z-direction, then the current direction through phase A− produces a flux in the negative z-direction. In the description, where the coil assembly comprises bipolar windings (also referred to herein as coils), the windings may be referred to in pairs. The individual windings composing each pair are wound opposite in polarity. The sense of the winding direction is indicated by a + or −. The bipolar coil structure is an exemplary illustration but the proposed magnetic core design process is also applicable to unipolar coil structures and/or configurations.

The term “polyphase” used herein refers to the transmitter and/or receiver in a wireless power transfer system having more than one phase. A polyphase system may generate rotating magnetic fields to transfer power.

The number of electric vehicles (EVs) in use is increasing, but long charging durations and limited driving range are still significant problems for broad EV adoption. Using wireless charging technology in parking lots, at bus stops, and on roads remains the most likely solution to extend driving range and decrease charging durations for EVs. The design of wireless charging pads is in development, and designing the magnetic component is the most important step since the magnetic part design determines the coupling and efficiency, requiring long simulation times using the best and most accurate method, which is finite element analysis (FEA). Achieving a low core loss and cost-effective magnetic core design with a strong magnetic coupling may require long simulation durations by using artificial intelligence methods and parametric analysis in FEA. To address this, the present solution provides a method for obtaining an effective core design. This method is called a topographic mapping (ATOM). The results show that ATOM can be used not only for the core design of a wireless charging pad but also for other magnetic core designs for different application areas. The different application areas include, but are not limited to, WPT system applications, electric machine applications, transformer design applications, inductor core design applications, shielding design applications, and/or thermal design applications for heat sinks. The core design of the present solution can be used with any magnetic structures. (unipolar, bipolar, polyphase, single phase, etc.). For example, the present solution can be used with a rectifying inverter with a single phase or any other number of phases.

Inductive components mostly include ferrite core materials and calculating the core loss is difficult. These losses may be determined using, for example, the following Steinmetz equation (1).

$${P}_{v} = {kf}^{α} {\hat{B}}^{β} \qquad ( 1 )$$

where Pv represents the core loss, \hat{B} is the peak flux density of a sinusoidal magnetic field in the core, f is the frequency, and k, α, and β are Steinmetz coefficients. The Steinmetz coefficients depend on the core material and can be found in the manufacturer's datasheet. This equation is valid only for a sinusoidal waveform. However, in power electronics, different waveforms may be used such as, for example, square waveforms, trapezoidal waveforms, or triangular waveforms. To overcome this challenge, the following mathematical equation (2) may be used to determine the core loss Pvn.

$${P}_{vn} = \frac{1}{T} {\int }_{0}^{T} {k}_{i} {\vert \frac{dB}{dt} \vert}^{a} {( Δ B )}^{β - α} dt \qquad ( 2 )$$

where ΔB is peak-to-peak flux density, and kᵢ is given by the following mathematical equation (3).

$${k}_{i} = \frac{k}{{{( 2 π )}^{α - 1} {\int \vert}_{0}^{2 π} cos θ \vert}^{α} {2}^{β - α} d θ} \qquad ( 3 )$$

The above equations show that core loss depends on the flux density, core material specifications, and frequency. The frequency for WPT systems is standardized by SAE International and is 85 kHz. Core material alternatives for this frequency are limited to products of ferrite manufacturers. Conversely, the flux density depends on the core thickness and ampere-turns. From mathematical equations (1) and (2), the core losses are directly related to the flux density value.

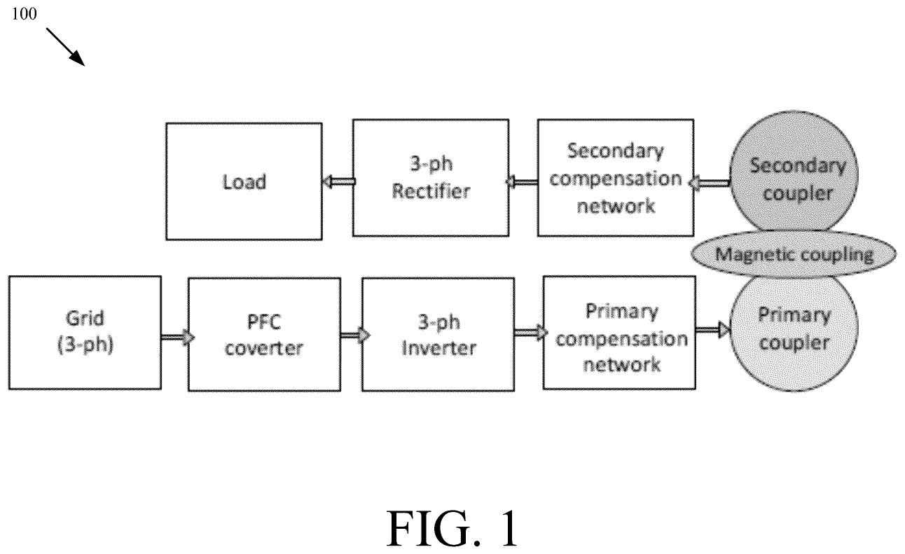

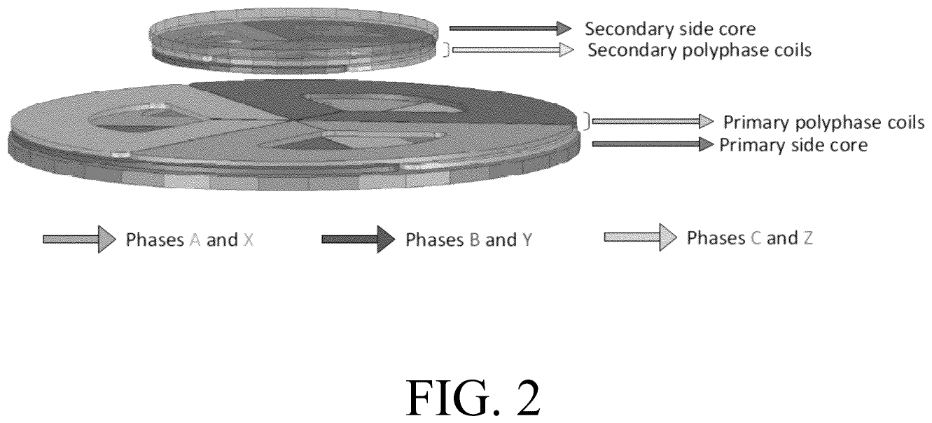

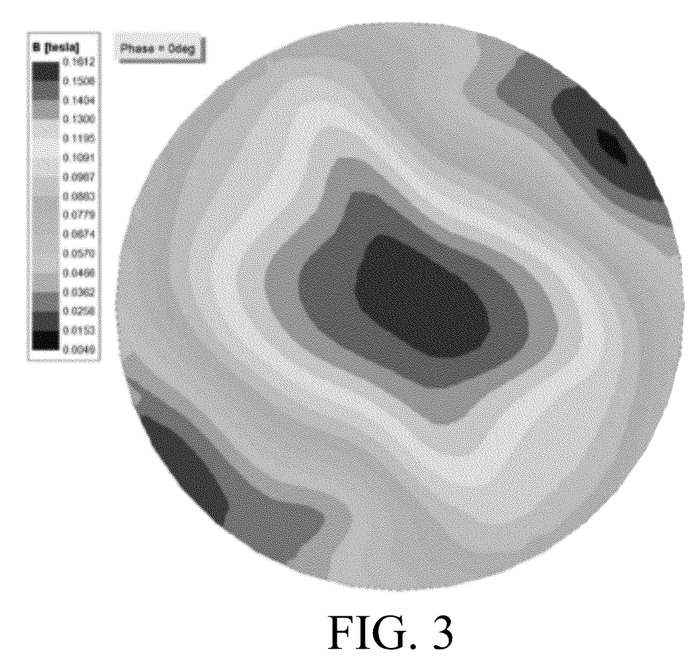

A magnetic field distribution-based approach for magnetic core design is described herein. As an example, a 100-kW polyphase WPT design was selected as an example application, and the disclosed method was applied to this coil design. Polyphase coil design has higher power density compared to other designs. A lumped circuit structure of a polyphase system 100 is shown in FIG. 1. A 3D view and representation of the polyphase coils and core parts for the primary and secondary sides are shown in FIG. 2.

The magnetic flux density distribution on the secondary side magnetic core material was obtained by FEA. This magnetic field density distribution is shown in FIG. 3. The field density has the maximum value in the center and gets lower on the sides. Consequently, the core material also must be thickest in the center and should change according to this scaling. The thickness of each layer is scaled by the flux density values of the layer. FIG. 3 shows only a capture of flux density distribution at a certain phase angle. Because the polyphase coil has a rotating magnetic field, the magnetic flux density plot will change as the field rotates. If the core is designed according to the specifications shown in FIG. 3, it will work for that instance and not cover the entire operation spectrum.

The flux density distributions at different phase angles should be considered.

Otherwise, the core loss and temperature may be higher for different phase angles. The field density distributions for every 10° phase angle of 360° may be obtained from the simulation results. A repeating pattern after every 60° with three main magnetic field density patterns is listed in TABLE 1.

TABLE 1
Different flux density distributions for a period

| Angle (°) | 0 | 60 | 120 | 180 | 240 | 300 | 360 |
|---|---|---|---|---|---|---|---|
| Case | A1 | A2 | A3 | A1 | A2 | A3 | A1 |

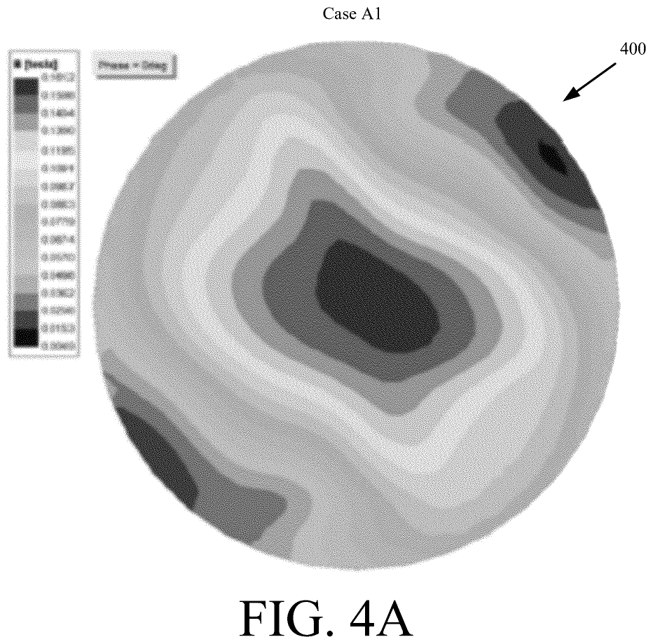

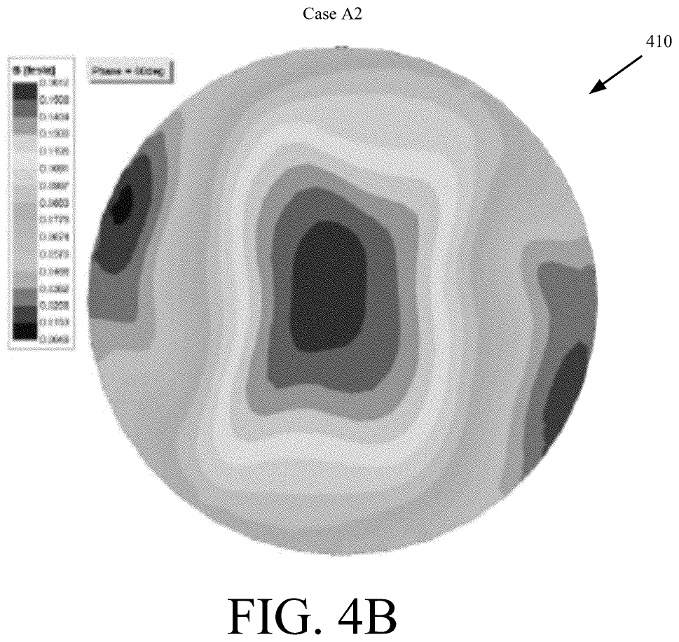

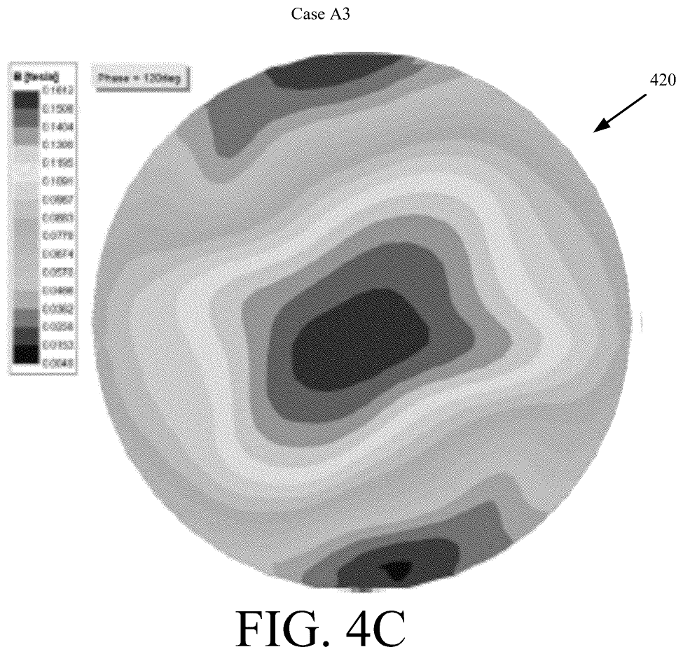

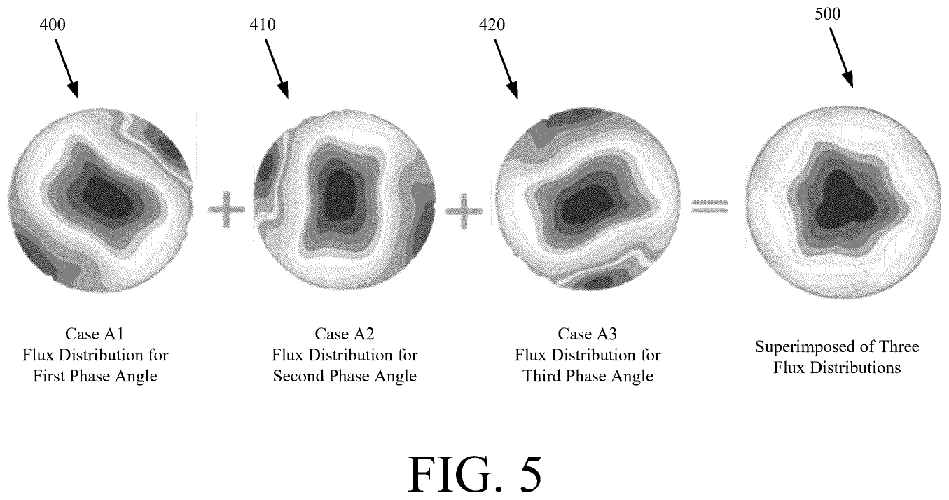

Some or all of the cases listed in TABLE 1 may be used to determine a final core shape. For example, in some scenarios, three cases A1, A2, A3 60° apart are used to determine a final core shape. The present solution is not limited to the particulars of this example. If more resolution is needed, more of the flux density distributions can be used at smaller angles (e.g., 5°, 10°). The captures for cases A1, A2, A3 taken from FEA results are shown in FIGS. 4A-4C. To create a 3D model, contour plot maps 400, 410, 420 may be drawn for each case and superimposed to obtain a contour plot map 500 for a final core shape as shown in FIG. 5.

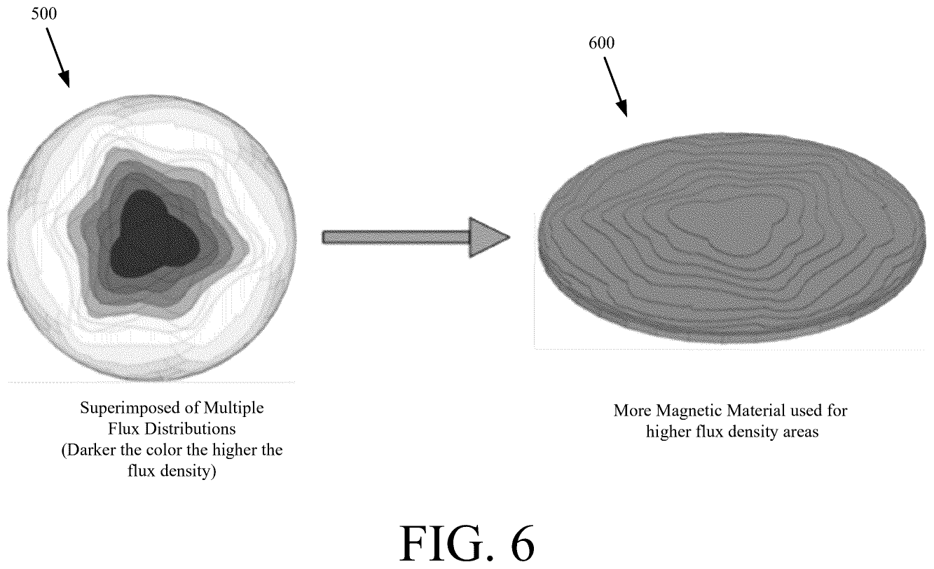

To avoid the high core losses and high-temperature issues, the final 3D core design should be created for the different cases. Three cases A1, A2, A3 have been considered in the scenario of FIGS. 4-5. Every layer with the same colors is summed together to obtain a new 3D core design. The final design contour map 500 and the associated 3D structure 600 are shown in FIG. 6. The 3D structure 600 has an ATOM design.

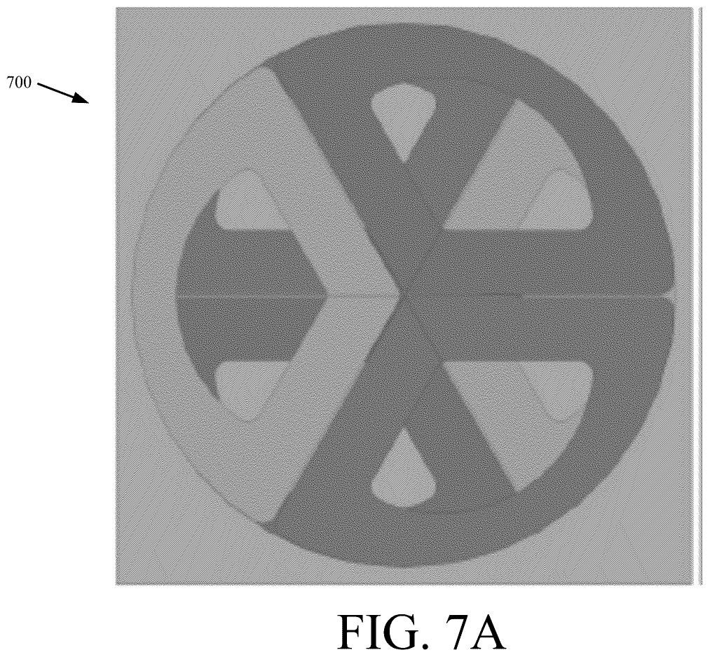

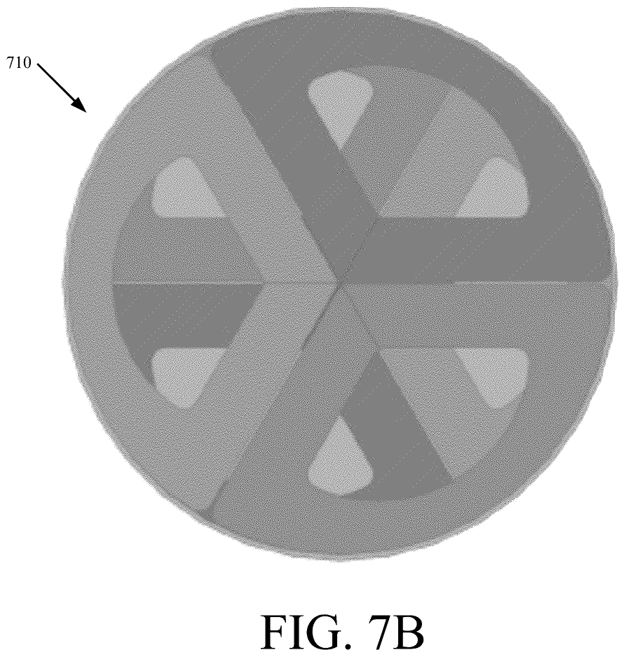

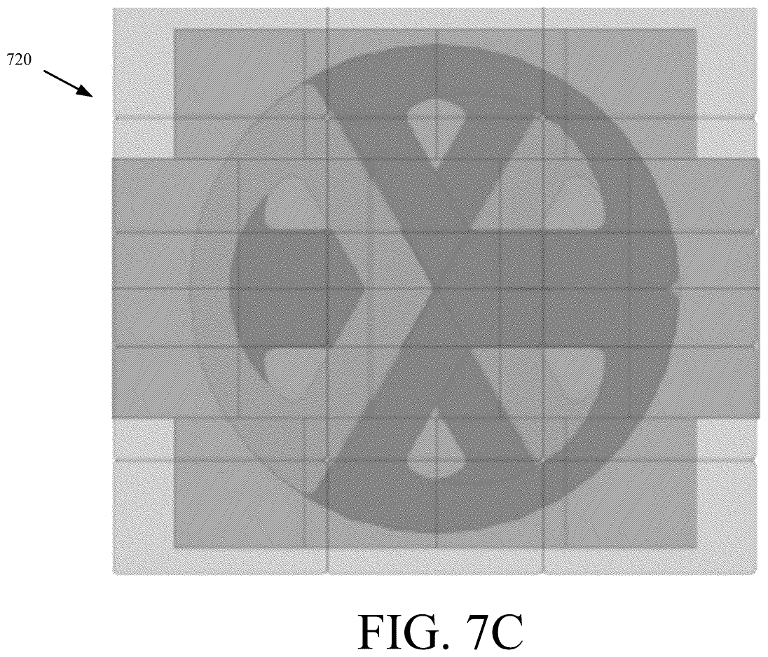

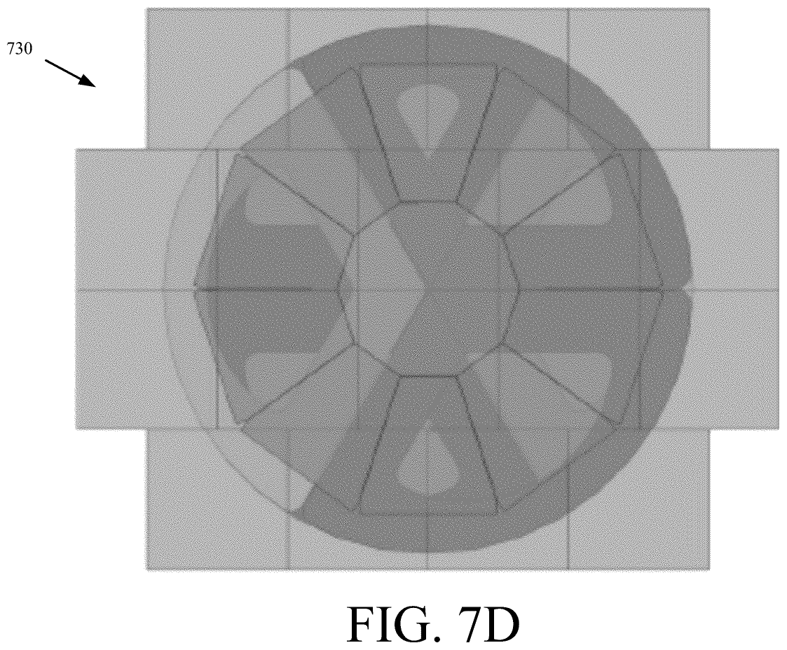

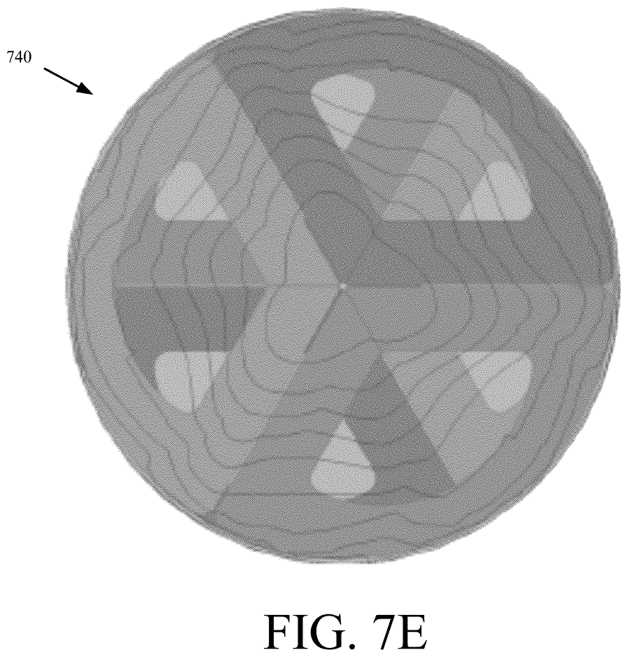

To highlight advantages of the disclosed ATOM design, different core designs were created and analyzed. The created core designs were placed above the secondary side polyphase coil, and FEA was performed. These different core designs are shown in FIGS. 7A-7C. Core 700 of FIG. 7A comprises a square core. Core 710 of FIG. 7B comprises a round core. Core 720 of FIG. 7C comprises a core with double layers. Core 730 of FIG. 7D comprises a core with double layers. A topographic mapping 740 is shown in FIG. 7E.

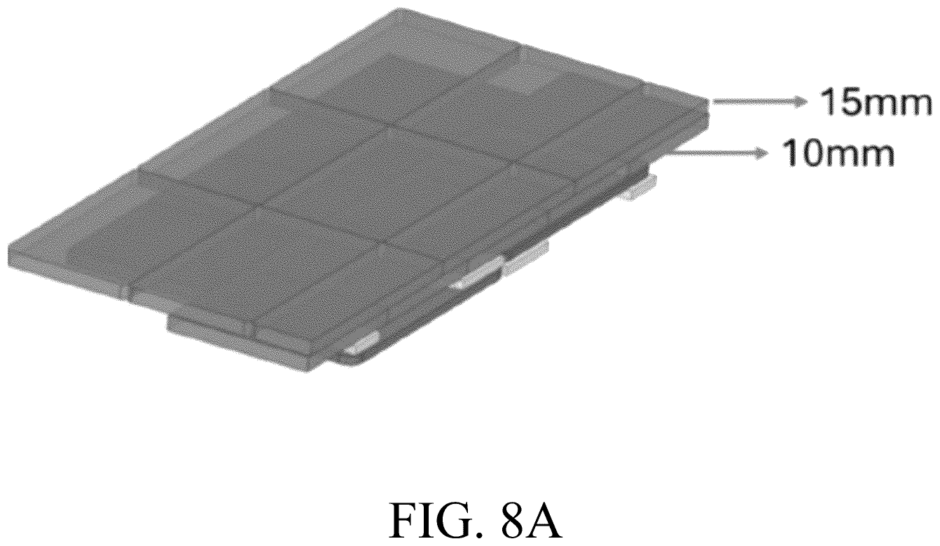

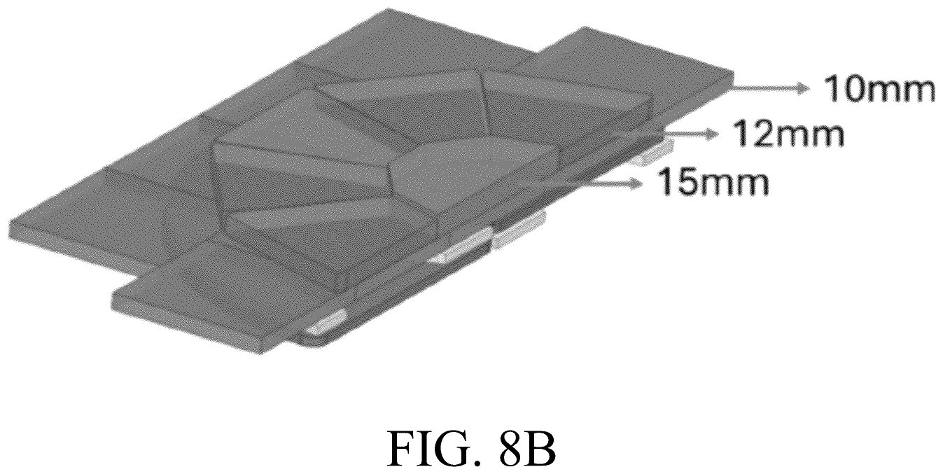

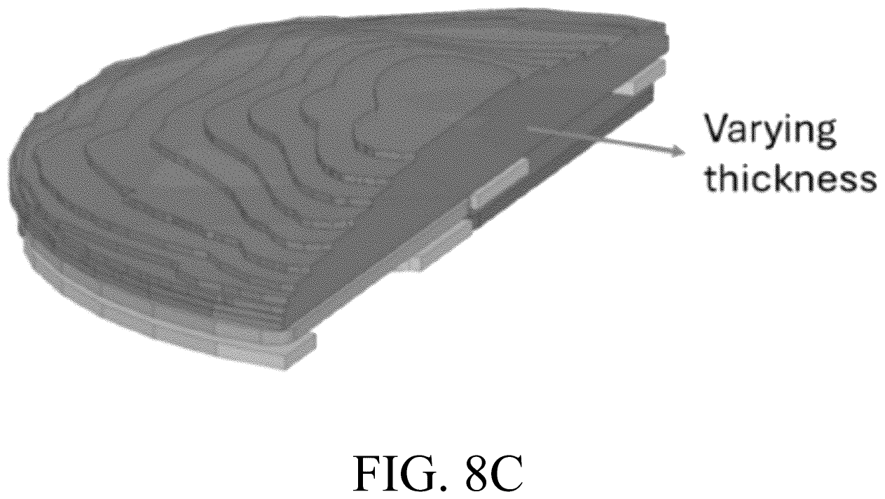

To illustrate the design details, half models of FIGS. 7A, 7B and 7E are shown in FIG. 8. The core thickness varies from layer to layer for the three different designs, as shown in FIG. 8. For the disclosed ATOM design which is shown in FIG. 8C, the scaling of the core thickness is determined according to the flux density scaling in FIG. 3. Each layer has a 2 mm thickness. The thickest part is the center (with a 36 mm thickness) because the magnetic flux density has the peak value at this section.

Coil design and inductance values have effects on power transfer efficiency. In FIG. 2, phases A, B and C present the primary side polyphase coils and phases X, Y and Z present the secondary side polyphase coils. The inductance matrix of the system may be given by following mathematical equation (4) comprising an inductance matrix.

$${L}_{polyphase} = [ \begin{matrix}{L}_{A} & {M}_{AB} & {M}_{A C} & {M}_{AX} & {M}_{AY} & {M}_{AZ} \\ {M}_{BA} & {L}_{B} & {M}_{BC} & {M}_{BX} & {M}_{BY} & {M}_{BZ} \\ {M}_{CA} & {M}_{CB} & {L}_{C} & {M}_{CX} & {M}_{CY} & {M}_{CZ} \\ {M}_{XA} & {M}_{XB} & {M}_{XC} & {L}_{X} & {M}_{XY} & {M}_{XZ} \\ {M}_{YA} & {M}_{YB} & {M}_{YC} & {M}_{YX} & {L}_{Y} & {M}_{YZ} \\ {M}_{ZA} & {M}_{ZB} & {M}_{ZC} & {M}_{ZX} & {M}_{ZY} & {L}_{Z}\end{matrix} ] \qquad ( 4 )$$

where L indicates self-inductance, and M indicates mutual inductance. In this matrix, an important point is to have a high mutual inductance value between reciprocal coils. These mutual inductances are M_{AX}, M_{BY}, and M_{CZ}. To compare the core loss and mutual inductance values for each design, FEAs were performed. The results are given in below TABLE 2.

TABLE 2
Comparison of different core shapes

| | Thickness | L_{A}, L_{B}, L_{C} | L_{X}, L_{Y}, L_{Z} | M_{AX}, M_{BY}, M_{CZ} | Core loss | Core volume |
|---|---|---|---|---|---|---|
| Design | (mm) | (μH) | (μH) | (μH) | (W) | (dm³) |
| Square | 25 | 14.6 | 13.09 | 3.45 | 78.86 | 4 |
| Round | 25 | 14.09 | 13.07 | 3.60 | 60.31 | 2.88 |
| Double-layer | Varied | 15.24 | 13.08 | 3.37 | 91.88 | 4.95 |
| rectangular | | | | | | |
| Double-layer | Varied | 15.15 | 13.09 | 3.37 | 161.71 | 2.82 |
| flower | | | | | | |
| ATOM | Varied | 14.08 | 13.06 | 3.62 | 59.57 | 2.50 |

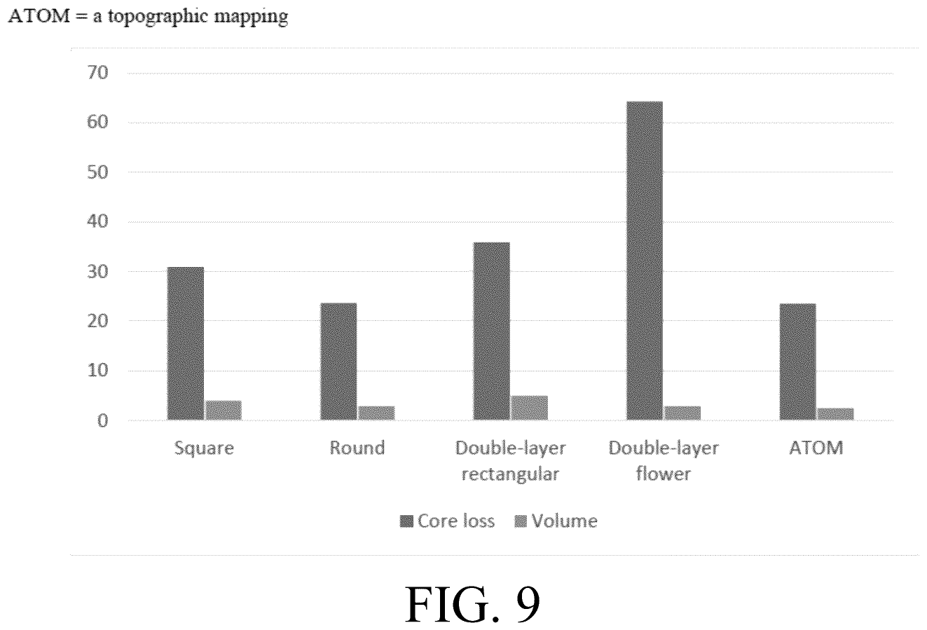

The results of TABLE 2 show that the core material volume can be decreased by 13.19% and 37.96% if compared with a bulk round core and square core, respectively. This means the disclosed design may be cost-effective. Also, the ATOM design has the highest mutual inductance value and the best coupling where it has the lowest core loss. The comparison of core loss and volume for each design is given in FIG. 9.

Mutual inductance is determined by the geometric alignment, coil dimensions, and relative positioning of the coils. Ideally, maximum power transfer occurs when the coils are perfectly aligned, meaning their magnetic fields optimally couple. However, real-world applications often involve lateral displacement which means misalignment between the primary and secondary side coils. In a polyphase WPT system, particularly between Phase A and Phase X, variations in mutual inductance due to lateral misalignment along the x and y axes can have an impact on power transfer capability.

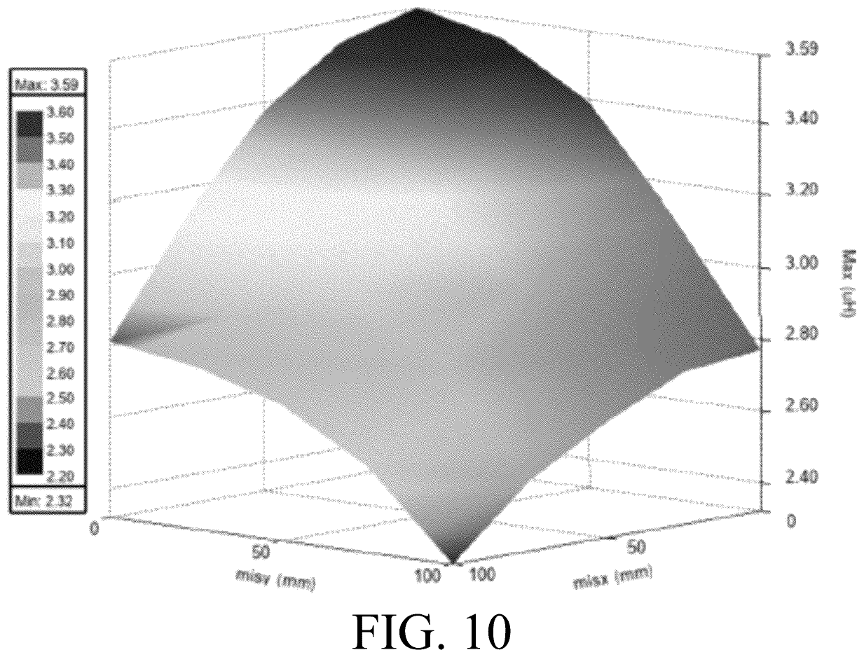

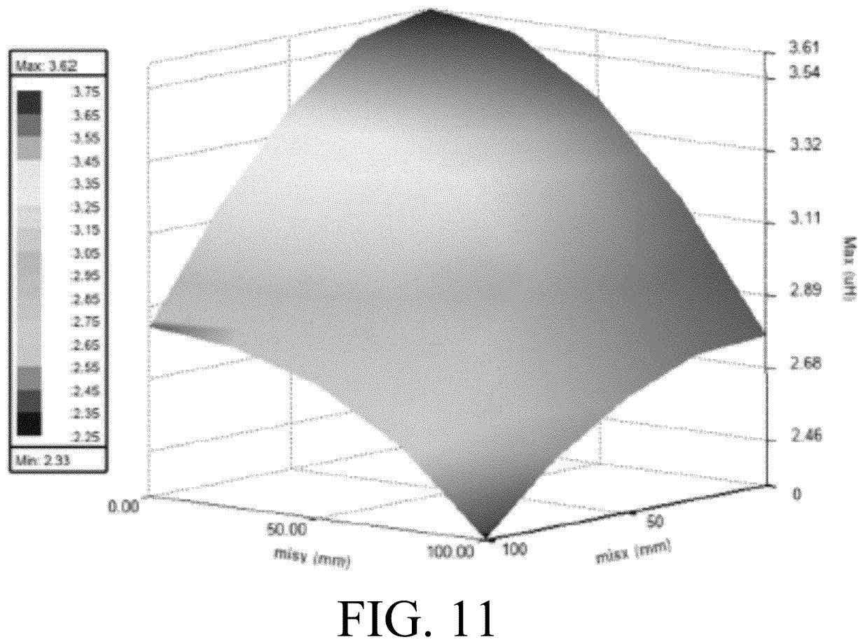

To see the performance of the disclosed magnetic core design in case of misalignment, the secondary coil may be shifted on the x and y axes for 10 cm and a parametric analysis may be performed. The same analysis may be performed for the bulky round core design to see a fair comparison. The results are shown in FIGS. 10-11, where the Mₐₓ shows the mutual inductance between Phase A and Phase X, and misx and misy shows the misalignment on the x and y axes, respectively. According to these results, both designs exhibit identical misalignment performance, with a maximum mutual inductance reduction of 35.46% in the worst-case scenario. However, in polyphase coil-based WPT systems, this reduction does not directly translate to the same percentage of power loss. One of the key advantages of such systems is their ability to compensate for misalignment—when mutual inductance decreases between two phases, the remaining phases begin to couple, enhancing overall misalignment tolerance and ensuring more stable power transfer.

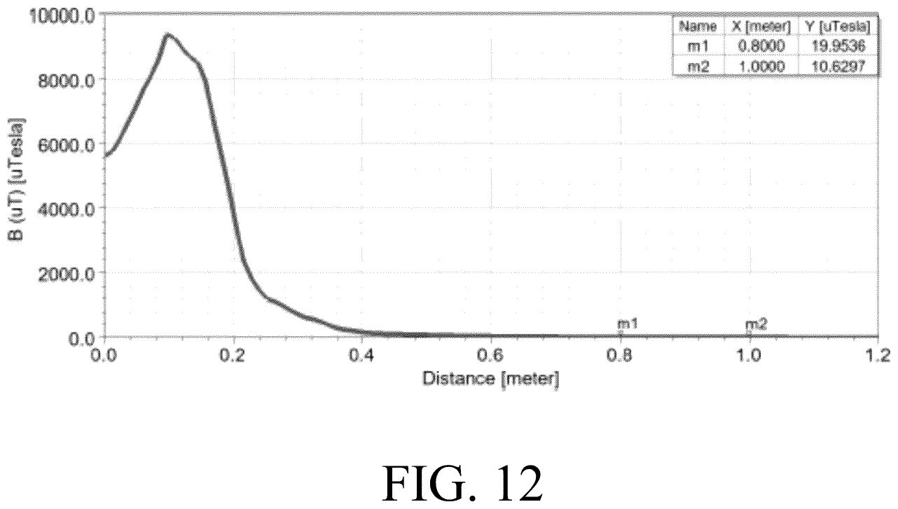

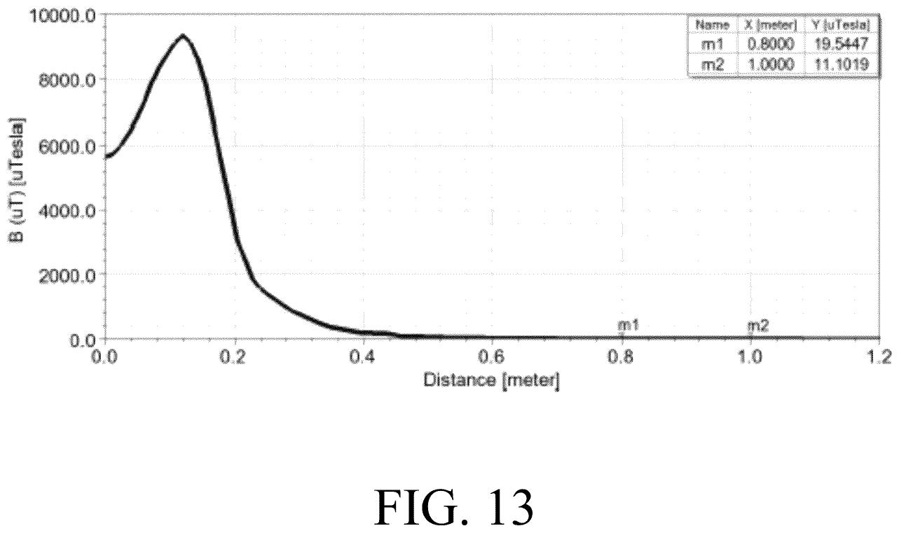

The other parameter to be evaluated to see the performance of a disclosed core design is field emissions. The magnetic field density B (uT) at 0.8 and 1 meter distances from the center of the primary and secondary coils were measured for Round magnetic and ATOM designs. These measurements are shown in FIGS. 12-13, respectively. The field results show that the ATOM design has the same field density values as the round core design at measured two points. According to the International Commission on Non-Ionizing Radiation Protection (ICNIRP) standard, the magnetic field density value should be below 27 uT. In the disclosed design, there is not an aluminum back plate for shielding purpose, even though, the field values are below 27 uT and comply with the standards.

The results show that the core design of the present solution has the lowest core loss, the best mutual inductance, and the lowest core volume if compared with existing topologies. Beside all these advantages, the core design of the present solution has the same misalignment tolerance and field emission values.

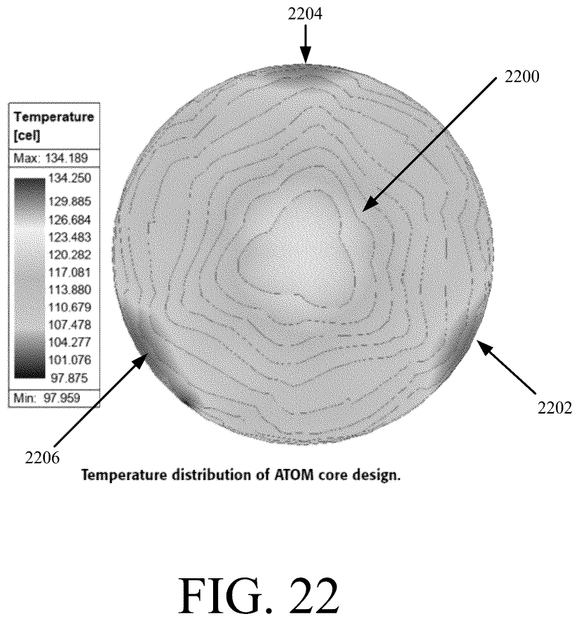

In addition to magnetic design, the proposed ATOM design not only helps reduce core loss and material usage but also helps to provide a more uniform temperature distribution over the magnetic core because the ATOM design increases the core thickness at higher flux density points where the temperature is expected to be higher. To demonstrate this capability, a thermal simulation was performed. The temperature distribution for the ATOM design is given in FIG. 22. The lighter center color represents a higher temperature area 2200 around sensors, while the darker edge colors represent lower temperature areas 2202, 2204, 2206 around sensors. Based on the temperature distribution of FIG. 22, a thermal or cooling system (e.g., a heat sink) may be fabricated with a variable thickness of thermally conductive material. For example, the thermal or cooling system may be thicker in area 2200 as opposed to areas 2202, 2204, 2206. The present solution is not limited in this regard.

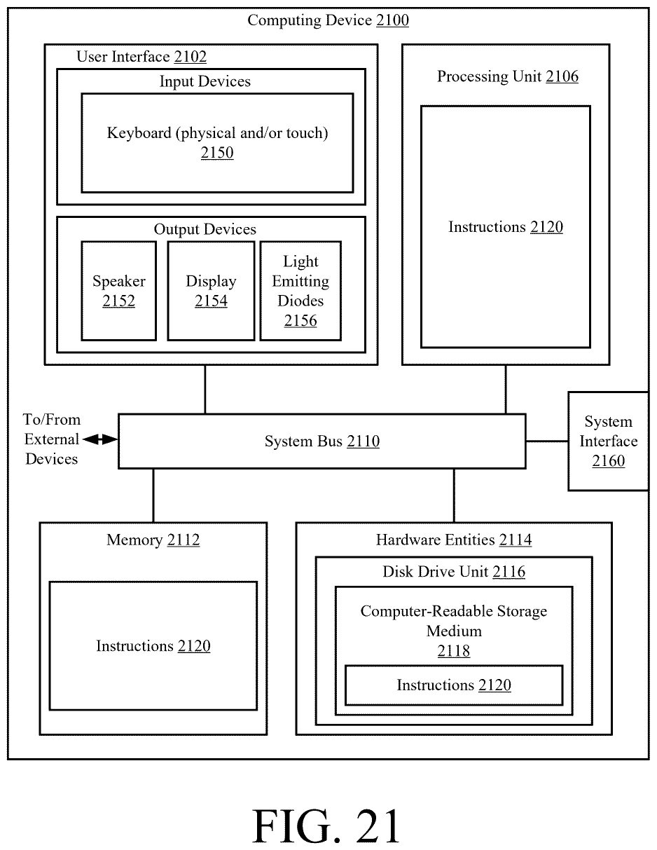

The thermal simulation results of FIG. 21 show that variable core thickness helps to reduce local heating problems and results in an improved uniform heat distribution. In addition, increasing the surface area of the magnetic core will help with heat dissipation. Mathematical equation (5) gives the relationship between surface area and heat dissipation.

$${Q}_{conv} = h \times A \times ( {T}_{surface} - {T}_{ambient} )$$

where Q_{conv}, h, A, T_{surface} and T_{ambient} relate the heat dissipated by convection (W), convective heat transfer coefficient (W/m2·K), surface area (m2), and the temperature difference between the surface and the environment (K) respectively. This equation illustrates that, as the surface area increases, the heat dissipation will also increase as in the main principle of heat sinks. Because the temperature of the secondary side of the magnetic couplers reaches an average temperature of 120° C., liquid cooling is needed for this 100 kW WPT application.

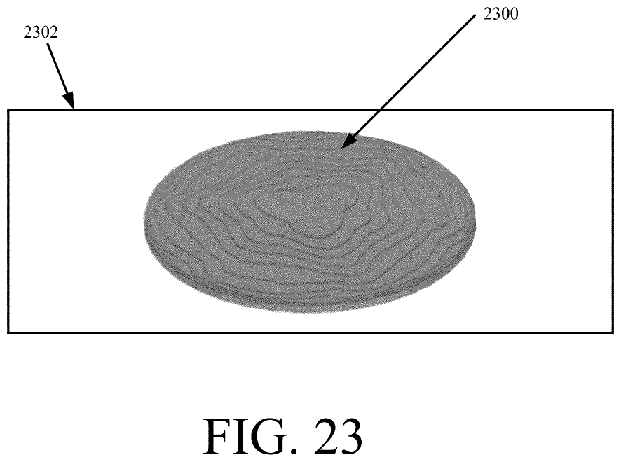

An illustration is provided in FIG. 23 showing a system implementing a method for providing a cooling system for a structure 2302. The structure is cooled using a thermal interface 2300 having a variable thickness. The variable thickness increases in areas of relatively higher temperature and decreases in areas of relatively lower temperature. The structure can include, but is not limited to, an electronic device or a magnetic core structure.

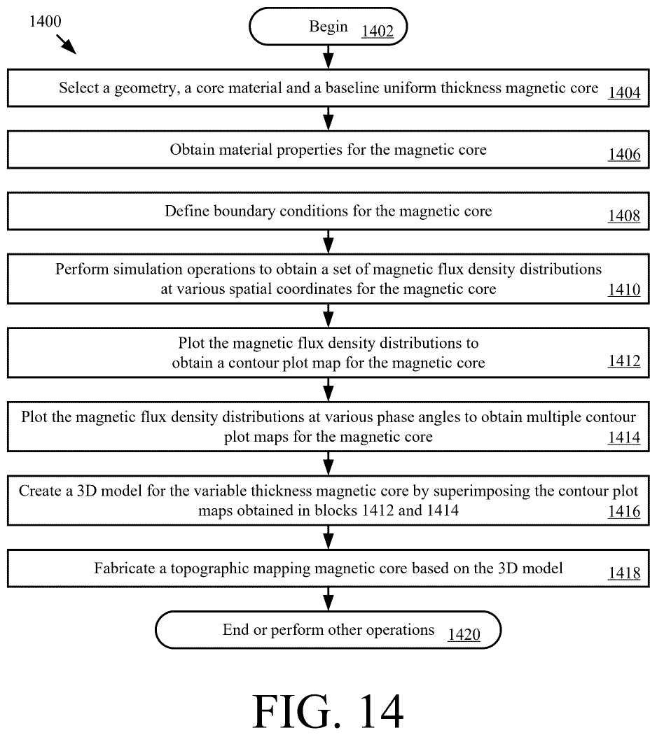

FIG. 14 provides a flow diagram of an illustrative method 1400 for designing magnetic cores. By using method 1400, the simulation time may be significantly decreased because an optimal core shape can be found by running relatively fewer simulations. Method 1400 may reduce the core volume and prevent the core material from high-temperature issues.

Method 1400 begins at block 1402 and continues to block 1404 where geometry, a core material and a baseline uniform thickness magnetic core are selected. The geometry can include, but is not limited to, core shape, coil windings, and/or air gaps. Next in block 1406, material properties for the magnetic core are obtained. The material properties can include, but are not limited to, B-H curve data for the core. Boundary conditions are defined in block 1408 for the magnetic core. The boundary conditions can include, but are not limited to, current density, magnetic potential, symmetry planes, magnetic permeability, and/or loss distribution.

In block 1410, simulation operations are performed to obtain a set of magnetic flux density values at various spatial coordinates for the magnetic core. The magnetic flux density distributions are plotted in block 1412 to obtain a contour plot map for the magnetic core (e.g., contour plot map 400 of FIGS. 4-5). The magnetic flux density distributions at various phase angles are plotted in block 1414 to obtain multiple contour plot maps for the magnetic core (e.g., contour plot maps 410, 420 of FIGS. 4-5). The more phase angles used between 0°-360° the higher the resolution.

A 3D model is created in block 1416 for the variable thickness magnetic core by superimposing the contour plot maps obtained in blocks 1412 and 1414. A topographic mapping magnetic core (e.g., magnetic core 600 of FIG. 6) is fabricated in block 1418 based on the 3D model. The topographic mapping magnetic core may be fabricated using a 3D printing technique, an additive manufacturing technique, a substrative manufacturing technique, a stack or layering based manufacturing technique, and/or a sintering manufacturing technique.

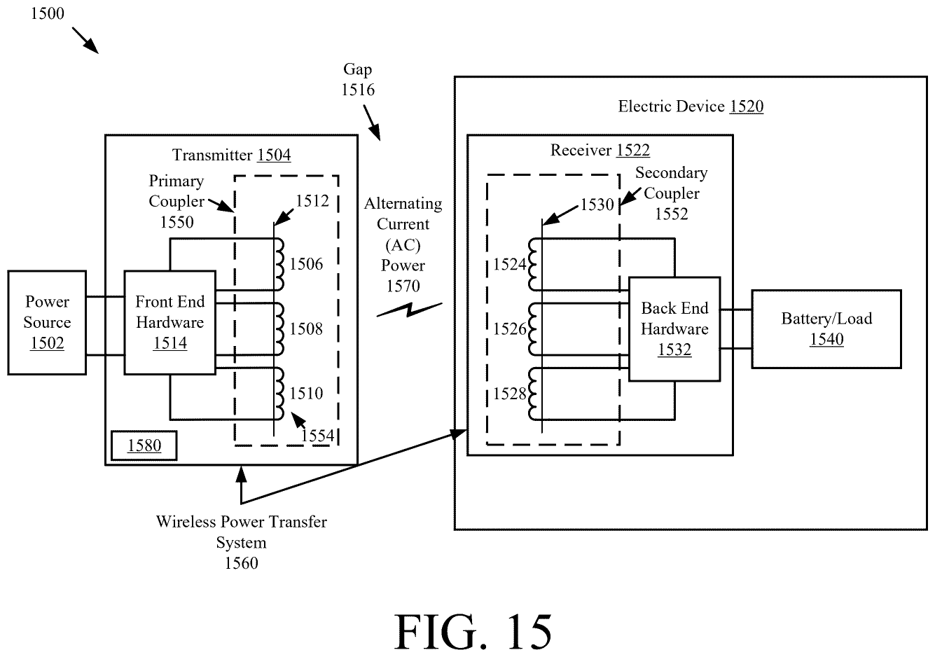

FIG. 15 provides an illustration of a system 1500 implementing the present solution. System 1500 comprises a power source 1502, a transmitter 1504, and an electronic device 1520. The transmitter 1504 is spaced apart from the electronic device 1520 such that a gap 1516 is provided therebetween. Electronic device 1520 can include, but is not limited to, an electric vehicle, a hybrid vehicle, or other electronic device with an internal battery that may be recharged.

During operation, power source 1502 provides input power to transmitter 1504. Power source 1502 can include, but is not limited to, the electrical grid or other alternating current (AC) power source. The input power can include, but is not limited to, 120 VAC at 60 Hz, 400 VAC at 50 Hz, or 480 VAC at 60 Hz. The present solution is not limited to AC input power. In some scenarios, power source 1502 comprises a direct current (DC) power source such as a high voltage battery. For example, an electric vehicle battery may be used to charge another electric vehicle battery.

Transmitter 1504 comprises front end hardware 1514 and a primary power coupler 1550. Front end hardware 1514 can include, but is not limited to, a power factor correction (PFC) converter, a DC-to-DC converter, a polyphase inverter, a compensation network, and/or other electronic devices. Each of the listed devices is well known. Still, it should be noted that the PFC converter comprises an electronic circuit configured to convert the AC input voltage to a DC voltage and the DC-to-DC converter comprises an electronic circuit configured to convert the DC input voltage to a DC bus voltage (e.g., 200V, 1000V, etc.). The polyphase inverter comprises an electronic circuit or device configured to convert the DC voltage into a polyphase alternating current. The electronic circuit of the polyphase inverter can include, but is not limited to, a plurality of switching pairs. The number of switching pairs may be dependent on the number of phases in coil assembly 1554 and polarity of the coils. Each switch of the switching pairs can include, but is not limited to, a field effect transistor (FET), a metal-oxide-semiconductor FET (MOSFET), or other switching element. Controller 1580 may act as a gate driver to turn ON and OFF each switching element of the switching pairs.

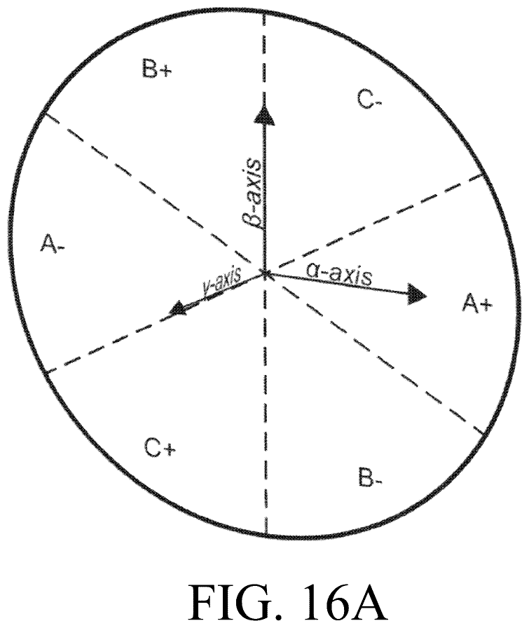

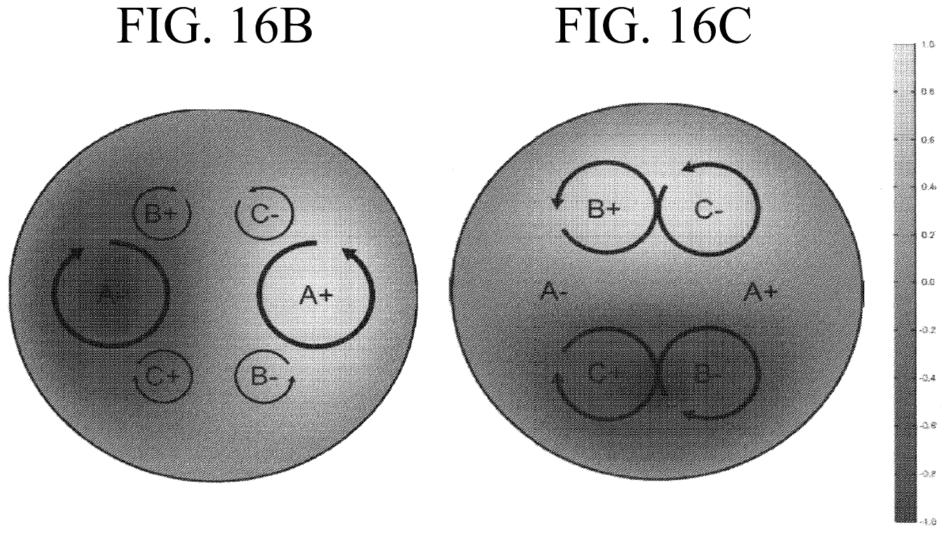

The compensation network comprises an electronic circuit configured to compensate for poor stability or impedance mismatches. In this regard, the compensation network may be tuned to achieve at least two independently excitable resonant modes for a single resonant frequency. For example, the two resonant modes may be α-mode (α-axis mode) and a β-mode (β-axis mode). FIG. 16A shows the relationship between the α-axis, the β-axis, the γ-axis and the coil placement. The α-axis is aligned with phase A. The β-axis is aligned with a midpoint between phases B and C. The γ-axis is orthogonal to both the α-axis and the β-axis and points out of the coil plane. Arrows in FIG. 16A represent the axis orientation. Once tuned, the α-mode and β-mode can be exited independently to produce a resonant rotating magnetic field. For example, they may be excited in quadrature (90-degrees phase shifted in time) to achieve high-efficiency constant power transfer. FIGS. 16B and 16C show examples of an α-mode and β-mode, respectively. In FIGS. 16B and 16C, the coils are not explicitly shown, however, the location is represented by letters A+, A−, B+, B−, C+ and C−, which are bipolar coils for the three-phases, A, B and C. The circular arrows represent the in-plane electrical current for each phase. As can be seen in the figure, the direction of the arrow for the different polarity is opposite. For example, for coil A+, the direction is counter-clockwise. However for coil A−, the direction is clockwise. The magnitude and direction of the magnetic flux density (which is out of the plane) (e.g., out of the page) is represented by different shading. The magnitude is normalized relative to a maximum flux density for the a excitation mode (e.g., −1 to 1). As can be seen in FIG. 16B, the maximum flux density (close to 1 or −1) is aligned with the area where coils A+ or A− are located in the α-mode. However, as can be seen in FIG. 16C, in the β-mode, the flux density is rotated such that the maximum flux density (close to 1 or −1) is located in an area where coils B+, B−, C+ and C− are located.

Referring back to FIG. 15, the output of the front end hardware 1514 is passed to the primary power coupler 1550. Primary power coupler 1550 is configured to wirelessly transmit AC power 1570 using the coil assembly 1554. AC power 1570 can include, but is not limited to, a high-frequency AC power in a range of 25-250 KW, a high-frequency AC power is about 100 kW, a high-frequency AC power with a fundamental frequency in a range of 10-100 kHz, and/or a high-frequency AC power with a fundamental frequency equal to or about 85 kHz. It should be noted here that the 100 kW power level is exemplary and the proposed magnetic core design is applicable to any power transfer level (e.g., 22 kW, 50 kW, 300 kW, etc.).

Coil assembly 1554 may (i) comprise one or more layers of coils and/or (ii) be unipolar or bipolar. In the bipolar scenarios, coil assembly 1554 may comprise three primary-side bipolar coils 1506, 1508, 1510 backed by a primary-side magnetic core 1512. Coils 1506, 1508, 1510 can include, but are not limited to, polyphase coils. The bipolar coil pairs are physically separated from each other but connected to each other so that multiple AC currents are produced. The AC currents are out of phase with each other.

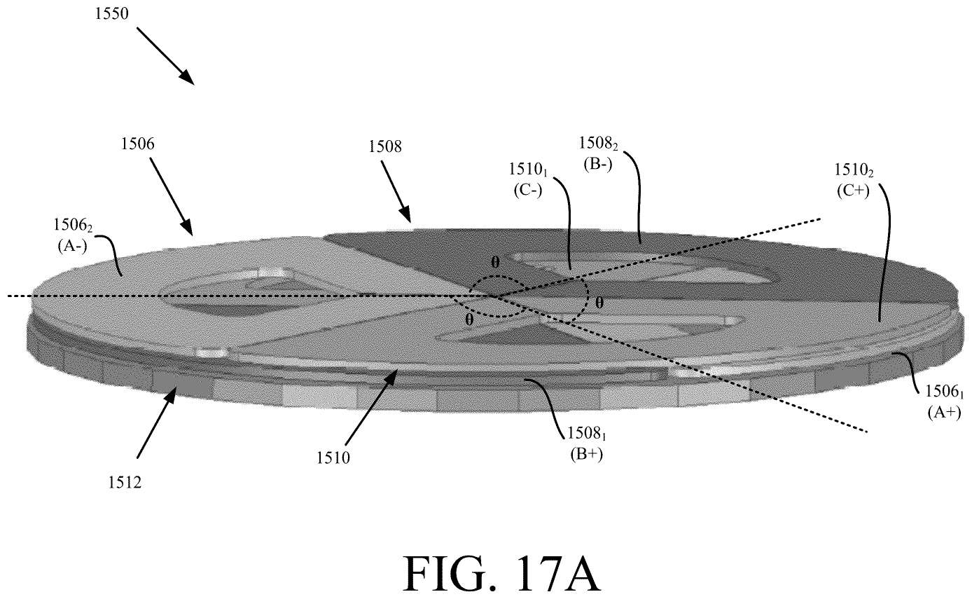

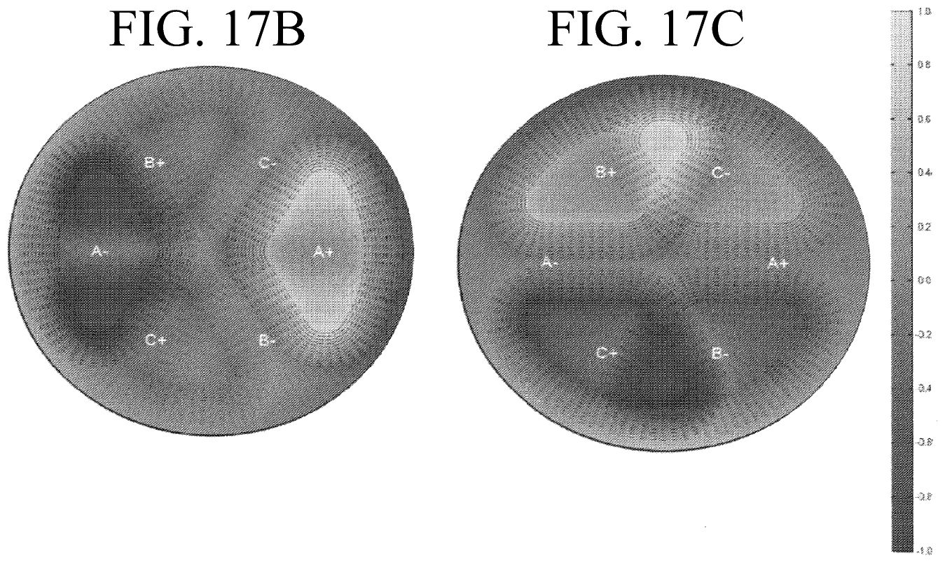

An illustrative architecture for primary power coupler 1550 is shown in FIG. 17A. This architecture comprises a three-phase bipolar coil assembly having a double layer (also referred to as dual layers or two layers). Coils having one polarity (e.g., A+, B+ and C+) are arranged on one layer, whereas coils having another polarity (e.g., A−, B−, and C−) are arranged on the other layer. The coils are staggered in the stacked direction. For example, the coils may be staggered by 60°. On each layer, each coil 1506, 1508, 1510 occupies a third of the circumference of the layer, e.g., θ=120°. The coils having different polarity are positioned on opposite sides of the layer. For example, coil 1506₁ with polarity A+ is located on the bottom side of the layer while coil 1506₂ with polarity A− is located on the top side of the layer. Similarly, coil 1508₁ with polarity B+ is located on the bottom side of the layer while coil 1508₂ with polarity B− is located on the top side of the layer. Likewise, 1510₁ with polarity C+ is located on the bottom side of the layer while coil 1510₂ with polarity C− is located on the top side of the layer. The coils with the same phase may be connected in series. Magnetic core 1512 comprises a planar magnetic core with a generally or substantially round perimeter shape. Magnetic core 1512 may be formed of ferrite or other magnetic material. Coils 1506₁, 1506₂, 1508₁, 1508₂, 1510₁, 1510₂ are disposed on magnetic core 1512. The coils 1506₂, 1508₂, 1510₂ on the top layer are farther from the magnetic core 1512 than the coils 1506₁, 1508₁, 1510₁ on the bottom layer. The windings on one layer will have one set of self- and mutual-inductance, and the windings on the other layer will have a different set of self- and mutual-inductances. However, since the positive and negative poles of each phase occur on different layers, when the individual phase coils in the double layer are connected in series, the overall system may have balanced inductances. A spacer may be provided between the two layers of coils. A cover or housing (not shown) may be provided to encompass all or a portion of the coil assembly. The present solution is not limited to the architecture shown in FIG. 17A. More than three-phases may be used in other scenarios. For example, five-phase, seven-phase, and higher phase systems may be used in coil assembly 1554. The number of phases is not limited to odd numbers.

FIGS. 17B-17C show examples of an α-mode and β-mode, respectively, for the double layer coil assembly of FIG. 17A. The arrows represent the magnetic and direction of the current density. The magnitude and direction of the magnetic flux density (z-component) is represented by different shading. Once again, the magnitude is normalized relative to a maximum flux density for the excitation mode (e.g., −1 to 1). Since the coils occupy a larger area in the double layer coil assembly, the areas showing higher electric current and magnetic flux are larger compared with the single layer coil assembly. FIG. 17B shows the electric current flowing in both layers. In the α-mode (FIG. 17B), the current density and the magnetic flux density is highest where phase A (e.g., coils A+ and A−) are located. In the β-mode (FIG. 17C), the current density and the magnetic flux density is highest for phases B and C. The flux density is rotated such that the maximum flux density (close to 1 or −1) is located in an area where coils B+, B−, C+ and C− are located and in particular, as shown in FIG. 17C, the maximum flux density is located where phases B and C overlap.

Referring back to FIG. 15, the transmitted AC power 1570 is received by receiver 1522 of electronic device 1520. It should be noted that transmitter 1504 resides off board the electronic device 1520, while receiver 1522 resides onboard the electronic device 1520. Transmitter 1504 and receiver 1522 collectively provide a polyphase wireless power transfer system 1560 for providing AC power to the electronic device 1520 from the AC power source 1502. In the scenario of FIG. 15, the polyphase wireless power transfer system 1560 comprises a three-phase wireless power transfer (3φ-WPT) system. The present solution is not limited in this regard.

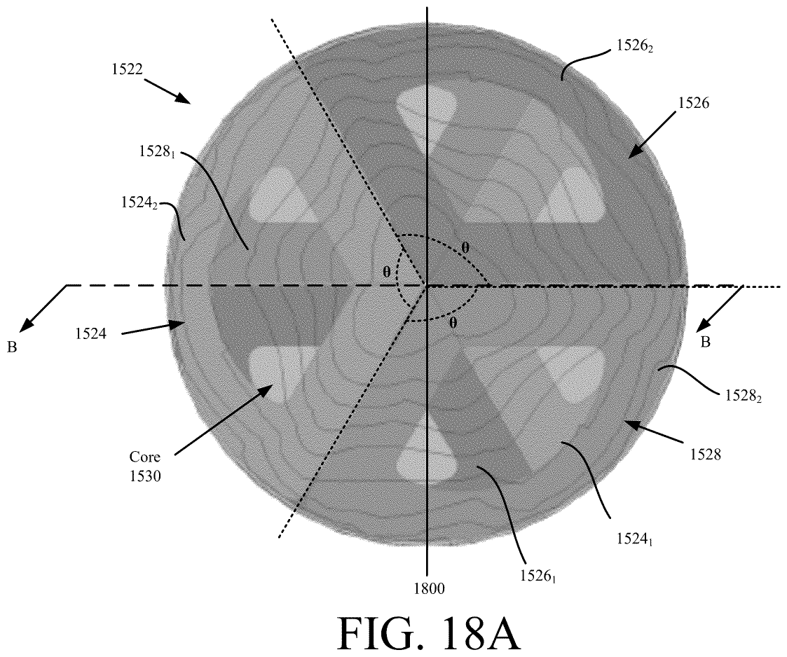

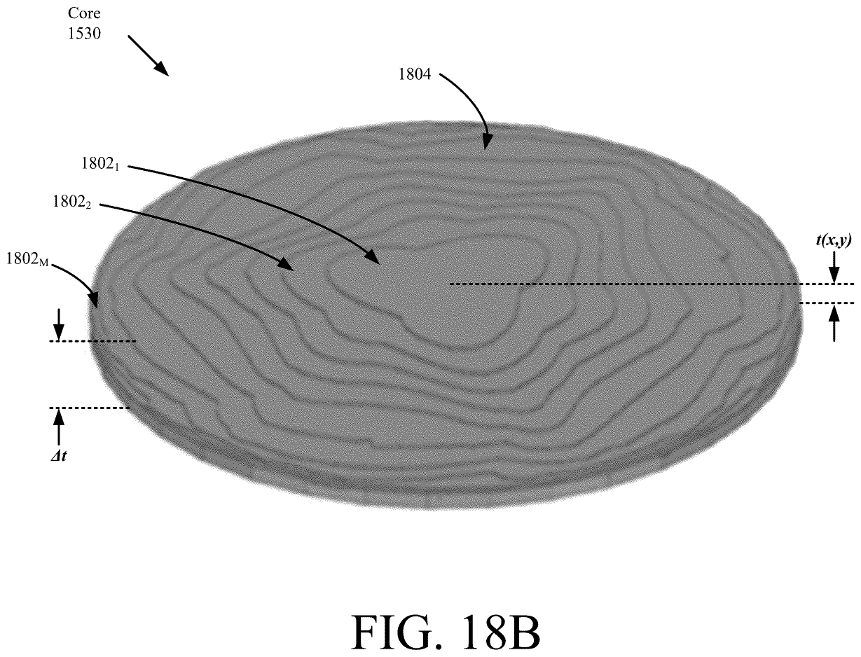

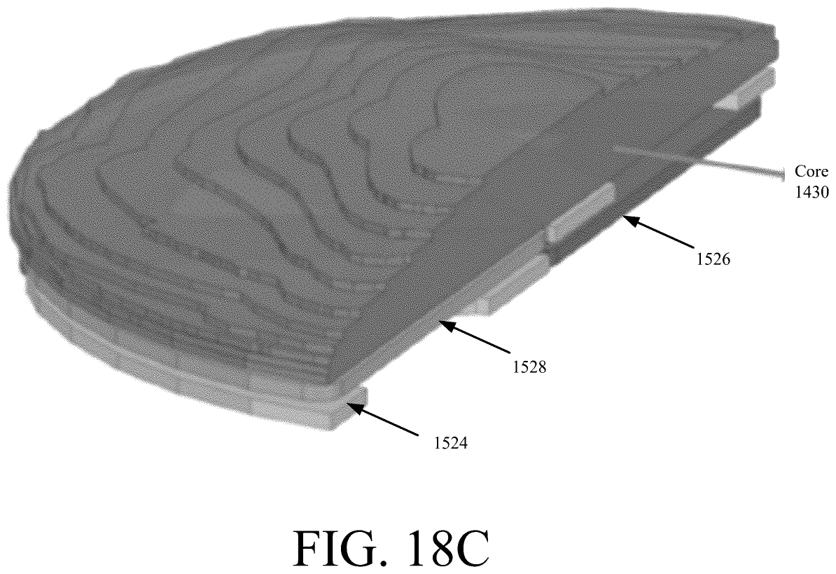

Receiver 1522 comprises a secondary coupler 1552 and backend hardware 1532. The secondary coupler 1552 includes three secondary-side bipolar coils 1524, 1526, 1528 backed by a secondary-side magnetic core 1530. Secondary-side magnetic core 1530 can include, but is not limited to, ferrite, and/or nanocrystalline material. Coils 1524, 1526, 1528 are configured to induce into core 1530 a spatially-dependent magnetic field distribution B(x, y; φ(t)) that rotates around an axis 1800 (see FIG. 18A) orthogonal to the three secondary-side bipolar coils 1524, 1526, 1528.

FIG. 18 shows an illustrative architecture for the secondary coupler 1552. Coils 1524, 1526, 1528 can comprise polyphase coils. The polyphase coils are physically separated from each other but connected to each other so that multiple AC currents are produced. The AC currents are out of phase with each other. In this regard, coils 1524, 1526, 1528 are rotated by an angle θ relative to each other. In the scenario of FIG. 18, portions 1524₁, 1526₁, 1528₁ on the first layer are rotated by an angle θ=120°. Similarly, portions 1524₂, 1526₂, 1528₂ on the second layer are rotated by an angle θ=120°. The first layer and second layer are rotated 180° relative to each other. In this way, secondary coupler 1552 has a repeating pattern of the three coils every 60°. The present solution is not limited in this regard since other angles can be used. Coils 1524, 1526, 1528 are disposed on magnetic core 1530.

Magnetic core 1530 comprises a non-planar magnetic core with a generally or substantially round perimeter shape. The non-planar design of the secondary-side magnetic core 1530 is visible in FIGS. 18B and 18C. Secondary-side magnetic core 1530 has a thickness t(x, y) that varies in a plane orthogonal to the axis 1800 like a linear combination of N instances of the spatially-dependent magnetic field distribution

$$t ( x , y ) ∼ {\sum }_{k = 1}^{N} B ( x , y ; {φ}_{k} ) , \qquad ( 5 )$$

where an instant phase is

$${φ}_{k} = \frac{( k - 1 ) π}{N} ,$$

k=1 . . . . N, and N is an integer that is greater than or equal to three.

Secondary-side magnetic core 1530 comprises a plurality of layers 1800₁, 1800₂, . . . 1800_{M} each having a thickness Δt. Δt may be defined by the following mathematical equation (6).

$$Δ t = \frac{{t}_{m ax} - {t}_{m i n}}{M} \qquad ( 6 )$$

where tₘᵢₙ represents a minimum value of the variable thickness, and tₘₐₓ represents a maximum thickness of the variable thickness.

The j^{th} layer has a respective contour yᵢ(x) that satisfies the condition defined by following mathematical equations (7)-(8).

$${B}_{m i n} + j Δ B = {\sum }_{k = 1}^{N} B ( x , {y}_{j} ( x ) ; {φ}_{k} ) . \qquad ( 7 )$$

$$Δ B = \frac{{B}_{ma x} - {B}_{m i n}}{M} \qquad ( 8 )$$

where Bₘᵢₙ represents a minimum value of the spatially-dependent magnetic field distribution, Bₘₐₓ represents a maximum value of the spatially-dependent magnetic field distribution, j=1, . . . , M, and M is an integer. The linear combination of instances of the spatially-dependent magnetic field distribution may be configured as shown in FIG. 5. In some scenarios, the number of instances of the spatially-dependent magnetic field distribution is N=3. The thickness may vary as

$$t ( x , y ) ∼ [ B ( x , y ; \frac{π}{3} ) + B ( x , y ; \frac{2 π}{3} ) + B ( x , y ; π ) ] .$$

Referring back to FIG. 15, backend hardware 1532 is coupled to across secondary coupler 1552. Back end hardware 1532 can include, but is not limited to, a compensation network, a polyphase rectifier, and/or other electronic devices. The compensation network comprises an electronic circuit configured to compensate for poor stability or impedance mismatches. The polyphase rectifier comprises an electrical circuit or device configured to convert polyphase AC current into DC current. The DC current is provided to battery 1540 for charging or recharging the same. Battery 1540 may supply power to load. Load can include, but is not limited to, a vehicle battery or other electric device powered by a rechargeable internal power source.

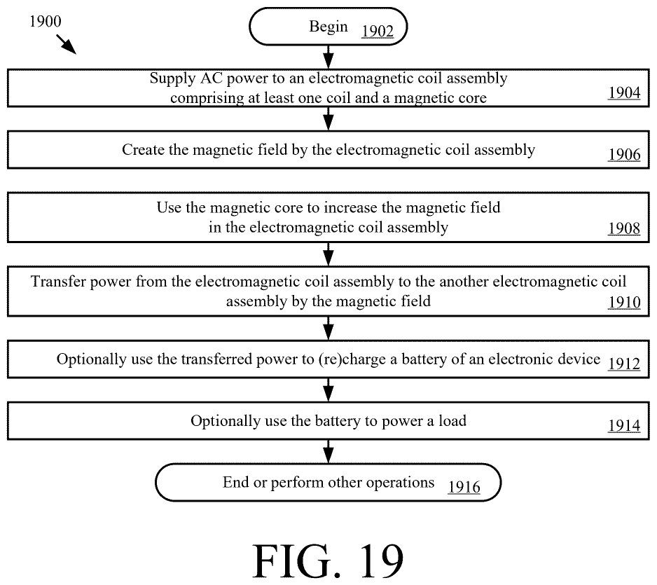

FIG. 19 provides a flow diagram of an illustrative method 1900 for providing a magnetic field. Method 1900 begins at block 1902 and continues to block 1904 where AC power is supplied to an electromagnetic coil assembly (e.g., primary coupler 1550 of FIG. 15) comprising at least one coil (e.g., coil(s) 1506, 1508, 1510 of FIG. 15) and a magnetic core (e.g., core 1512 of FIG. 15). Next in block 1906, the magnetic field is created by the electromagnetic coil assembly. The magnetic core is used in block 1908 to increase the magnetic field in the electromagnetic coil assembly. The magnetic core has a variable thickness which increases in areas (e.g., area 18021 of FIG. 18) of relatively higher magnetic flux density and decreases in areas (e.g., areas 1802M of FIG. 18) of relatively lower magnetic flux density. The magnetic core is defined by a contoured surface (e.g., contoured surface 1804 of FIG. 18) that is a function of a linear combination (e.g., linear combination 500 of FIGS. 5-6) of a plurality of instances of a spatially-dependent magnetic field distribution of the electromagnetic coil assembly (e.g., instances 400, 410, 420 of FIGS. 4-5). The magnetic flux density may be uniform or non-uniform across the magnetic core. The magnetic core may be fabricated based on a 3D model created by superimposing a plurality of contour plot maps showing magnetic flux density distributions at various phase angles. The contour plot maps may be created by performing simulation operations to generate a set of magnetic flux density distributions at various spatial coordinates for the magnetic core. The magnetic core may be fabricated using a 3D printing technique, an additive manufacturing technique, a substrative manufacturing technique, a stack or layering based manufacturing technique, and/or a sintering manufacturing technique.

In some scenarios, the electromagnetic coil assembly and another electromagnetic coil assembly (e.g., secondary coupler 1552 of FIG. 15) collectively comprise a wireless power transfer system (e.g., wireless power transfer system 1560 of FIG. 15). Accordingly, method 1900 continues to block 1910 where power is transferred from the electromagnetic coil assembly to the another electromagnetic coil assembly by the magnetic field. The transferred power may optionally be used in block 1912 to (re) charge a battery (e.g., battery 1540 of FIG. 15) of an electronic device (e.g., electronic device 1520 of FIG. 15). The electronic device may comprise a vehicle. The electromagnetic coil assembly may reside off board the electronic device while the another electromagnetic coil assembly may reside on board the electronic device.

The battery may optionally be used in block 1914 to power a load. Subsequently, method 1900 continues to block 1916 where it ends or other operations are performed (e.g., return to block 1902).

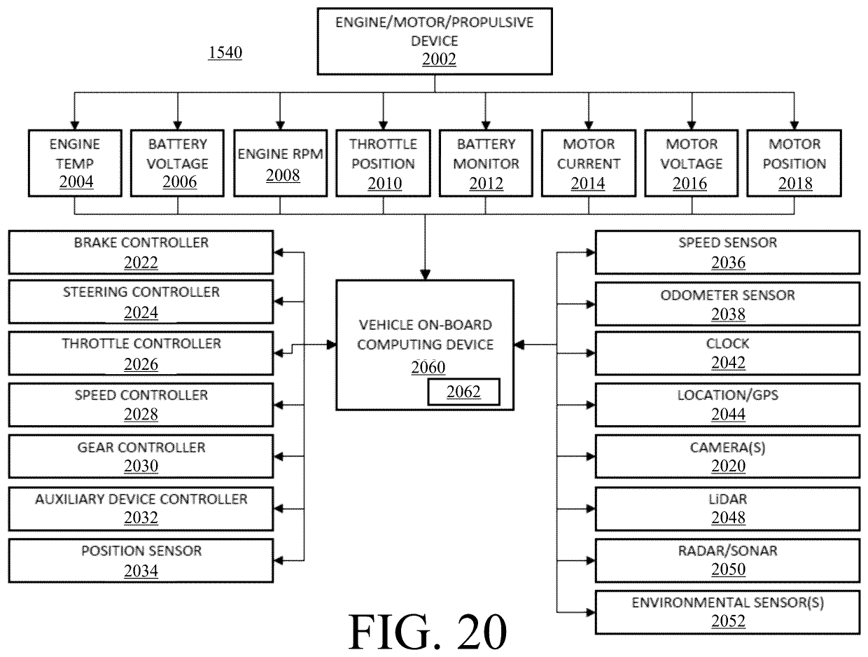

FIG. 20 shows an illustrative architecture 2000 for a vehicle. The vehicle can include, but is not limited to, an electric vehicle, a hybrid vehicle, a gas powered vehicle, or any other type of vehicle. Load 1540 of FIG. 15 can have the same or similar system architecture as shown in FIG. 20. Thus, the following discussion of architecture 2000 is sufficient for understanding one possible architecture for load 1540 of FIG. 15. A battery may be used to power one or more components of the load which may or may not comprise the vehicle's propulsion system.

Architecture 2000 includes an engine, motor or propulsive device (e.g., a thruster) 2002 and various sensors 2004-2018 for measuring various parameters of the vehicle. Sensors 2004-2018 may include, for example, an engine temperature sensor 2004, a battery voltage sensor 2006, an engine Rotations Per Minute (RPM) sensor 2008, a throttle position sensor 2010, a battery monitoring system 2012 (to measure current, voltage and/or temperature of the battery), motor current sensor 2014, voltage sensor 2016, and/or motor position sensors 2018. Other sensors may also be provided. The other second include, but are not limited to, a position sensor 2034 (e.g., an accelerometer, gyroscope and/or inertial measurement unit), a speed sensor 2036, and/or an odometer sensor 2038. A clock 2042 may be provided that the system uses to determine vehicle time during operation. Clock 2042 may be encoded into the vehicle onboard computing device 2060. It may be a separate device, or multiple clocks may be available.

Various other sensors may be provided that operate to gather information about the environment in which the vehicle is traveling. These sensors may include, but are not limited to, a location sensor 2044 (for example, a Global Positioning System (GPS) device), object detection sensors (e.g., camera(s) 2020), a LiDAR sensor system 2048, and/or a radar and/or a sonar system 2050. The sensors also may include environmental sensors 2052, such as a precipitation sensor and/or ambient temperature sensor. The object detection sensors may enable the vehicle to detect objects that are within a given distance range thereof in any direction, while the environmental sensors 2052 collect data about environmental conditions within the vehicle's area of travel.

During operations, information is communicated from the sensors to an onboard computing device 2060. The onboard computing device 2060 may be configured to analyze the data captured by the sensors and/or data received from data providers, and may be configured to optionally control operations of the vehicle based on the results of the analysis. For example, the onboard computing device 2060 may be configured to control: braking via a brake controller 2022; direction via a steering controller 2024; speed and acceleration via a throttle controller 2026; a motor speed controller 2028; a differential gear controller 2030; and/or other controllers.

Geographic location information may be communicated from the location sensor 2044 to the onboard computing device 2060, which may then access a map of the environment that corresponds to the location information to determine known fixed features of the environment such as streets, buildings, stop signs and/or stop/go signals. Captured images from the cameras 2020 and/or object detection information captured from sensors such as LiDAR 2048 are communicated from those sensors to the onboard computing device 2060. The object detection information and/or captured images are processed by a perception module of the onboard computing device 2060 to detect objects in proximity to the vehicle. Any known or to be known technique for making an object detection based on sensor data and/or captured images may be used in the embodiments disclosed in this document. Onboard computing device 2060 generates and/or updates trajectories for the vehicle based on the object detections made by the perception module 2024.

Referring now to FIG. 21, there is shown an illustrative architecture for a computing device 2100. The load 1540 of FIG. 15 and/or vehicle on-board computing device 2060 of FIG. 209 is/are the same as or similar to computing device 2100. As such, the discussion of computing device 2100 is sufficient for understanding the components 1540, 2060.

Computing device 2100 may include more or less components than those shown in FIG. 21. However, the components shown are sufficient to disclose an illustrative solution implementing the present solution. The hardware architecture of FIG. 21 represents one implementation of a representative computing device configured to receive information, process the receive information, transmit information and/or control operations of one or more robots, as described herein. As such, the computing device 2100 of FIG. 21 implements at least a portion of the method(s) described herein.

Some or all components of the computing device 2100 can be implemented as hardware, software and/or a combination of hardware and software. The hardware includes, but is not limited to, one or more electronic circuits. The electronic circuits can include, but are not limited to, passive components (e.g., inductors and capacitors) and/or active components (e.g., power electronic converters and/or controllers (e.g., controllers comprising microprocessors). The passive and/or active components can be adapted to, arranged to and/or programmed to perform one or more of the methodologies, procedures, or functions described herein.

As shown in FIG. 21, the computing device 2100 comprises a user interface 2102, a Central Processing Unit (CPU) 2106, a system bus 2110, a memory 2112 connected to and accessible by other portions of computing device 2100 through system bus 2110, a system interface 2160, and hardware entities 2114 connected to system bus 2110. The user interface can include input devices and output devices, which facilitate user-software interactions for controlling operations of the computing device 2100. The input devices include, but are not limited to, a physical and/or touch keyboard 2150. The input devices can be connected to the computing device 2100 via a wired or wireless connection (e.g., a Bluetooth® connection). The output devices include, but are not limited to, a speaker 2152, a display 2154, and/or light emitting diodes 2156. System interface 2160 is configured to facilitate wired or wireless communications to and from external devices (e.g., network nodes such as access points, etc.).

At least some of the hardware entities 2114 perform actions involving access to and use of memory 2112, which can be a random access memory (RAM), a disk drive, flash memory, a universal serial bus (USB) drive and/or another hardware device that is capable of storing instructions and data. Hardware entities 2114 can include a disk drive unit 2116 comprising a computer-readable storage medium 2118 on which is stored one or more sets of instructions 2120 (e.g., software code) configured to implement one or more of the methodologies, procedures, or functions described herein. The instructions 2120 can also reside, completely or at least partially, within the memory 2112 and/or within the CPU 2106 during execution thereof by the computing device 2100. The memory 2112 and the CPU 2106 also can constitute machine-readable media. The term “machine-readable media”, as used here, refers to a single medium or multiple media (e.g., a centralized or distributed database, and/or associated caches and servers) that store the one or more sets of instructions 2120. The term “machine-readable media”, as used here, also refers to any medium that is capable of storing, encoding or carrying a set of instructions 2120 for execution by the computing device 2100 and that cause the computing device 2100 to perform any one or more of the methodologies of the present disclosure.

Without excluding further possible embodiments, certain example embodiments are summarized in the following clauses:

Clause 1: A method for providing a magnetic field, comprising: supplying AC power to an electromagnetic coil assembly comprising at least one coil and a magnetic core; creating the magnetic field by the electromagnetic coil assembly; and using the magnetic core to increase the magnetic field in the electromagnetic coil assembly, wherein the magnetic core has a variable thickness which increases in areas of relatively higher magnetic flux density and decreases in areas of relatively lower magnetic flux density.

Clause 2: The method according to clause 1, further comprising wherein the magnetic core is defined by a contoured surface that is a function of a linear combination of a plurality of instances of a spatially-dependent magnetic field distribution of the electromagnetic coil assembly.

Clause 3: The method according to any of the preceding method clauses, wherein the magnetic flux density is uniform or non-uniform across the magnetic core.

Clause 4: The method according to any of the preceding method clauses, wherein the magnetic core is fabricated based on a 3D model created by superimposing a plurality of contour plot maps showing magnetic flux density distributions at various phase angles.

Clause 5: The method according to any of the preceding method clauses, wherein the plurality of contour plot maps are created by performing simulation operations to generate a set of magnetic flux density distributions at various spatial coordinates for the magnetic core.

Clause 6: The method according to any of the preceding method clauses, wherein the magnetic core is fabricated using a 3D printing technique, an additive manufacturing technique, a substrative manufacturing technique, a stack or layering based manufacturing technique, and/or a sintering manufacturing technique. The substrative manufacturing technique can include, but is not limited to, milling or machining.

Clause 7: The method according to any of the preceding method clauses, wherein the electromagnetic coil assembly and another electromagnetic coil assembly collectively comprise a wireless power transfer system.

Clause 8: The method according to any of the preceding method clauses, further comprising transferring power from the electromagnetic coil assembly to the another electromagnetic coil assembly by the magnetic field.

Clause 9: The method according to any of the preceding method clauses, further comprising using the transferred power to (re) charge a battery of an electronic device.

Clause 10: The method according to any of the preceding method clauses, wherein the electronic device comprises a vehicle.

Clause 11: The method according to any of the preceding method clauses, wherein the electromagnetic coil assembly resides off board the electronic device and the another electromagnetic coil assembly resides on board the electronic device.

Clause 12: The method according to any of the preceding method clauses, wherein the electromagnetic coil assembly comprises a polyphase coil.

Clause 13: The method according to any of the preceding method clauses, wherein the electromagnetic coil assembly comprises a plurality of coils that are configured to induce into the magnetic core a spatially-dependent magnetic field distribution that rotates around an axis orthogonal to the plurality of coils.

Clause 14: A system, comprising: a power source configured to supply alternating current; an electromagnetic coil assembly comprising at least one coil configured to create a magnetic field when the alternating current pass therethrough and a magnetic core configured to increase the magnetic field; wherein the magnetic core has a variable thickness which increases in areas of relatively higher magnetic flux density and decreases in areas of relatively lower magnetic flux density.

Clause 15: The system according to any of the preceding system clauses, wherein the magnetic core is defined by a contoured surface that is a function of a linear combination of a plurality of instances of a spatially-dependent magnetic field distribution of the electromagnetic coil assembly.

Clause 16: The system according to any of the preceding system clauses, wherein the magnetic flux density is uniform or non-uniform across the magnetic core.

Clause 17: The system according to any of the preceding system clauses, wherein the magnetic core is fabricated based on a 3D model created by superimposing a plurality of contour plot maps showing magnetic flux density distributions at various phase angles.

Clause 18: The system according to any of the preceding system clauses, wherein the plurality of contour plot maps are created by performing simulation operations to generate a set of magnetic flux density distributions at various spatial coordinates for the magnetic core.

Clause 19: The system according to any of the preceding system clauses, wherein the magnetic core is fabricated using a 3D printing technique, an additive manufacturing technique, a substrative manufacturing technique, a stack or layering based manufacturing technique, and/or a sintering manufacturing technique.

Clause 20: The system according to any of the preceding system clauses, wherein the electromagnetic coil assembly and another electromagnetic coil assembly collectively comprise a wireless power transfer system.

Clause 21: The system according to any of the preceding system clauses, wherein power is transferred from the electromagnetic coil assembly to the another electromagnetic coil assembly by the magnetic field.

Clause 22: The system according to any of the preceding system clauses, wherein the transferred power is used to (re) charge a battery of an electronic device.

Clause 23: The system according to any of the preceding system clauses, wherein the electronic device comprises a vehicle.

Clause 24: The system according to any of the preceding system clauses, wherein the electromagnetic coil assembly resides off board the electronic device and the another electromagnetic coil assembly resides on board the electronic device.

Clause 25: The system according to any of the preceding system clauses, wherein the electromagnetic coil assembly comprises a polyphase coil.

Clause 26: The system according to any of the preceding system clauses, wherein the electromagnetic coil assembly comprises a plurality of coils that are configured to induce into the magnetic core a spatially-dependent magnetic field distribution that rotates around an axis orthogonal to the plurality of coils.

Clause 27: A polyphase wireless power transfer system for wirelessly providing high-frequency AC power to an electric vehicle, comprising: an off-board transmitter comprising a primary coupler configured to wirelessly transmit the high-frequency AC power (the primary coupler comprising a plurality of primary-side coils backed by a primary-side core); and an on-board receiver comprising a secondary coupler configured to receive the high-frequency AC power when the primary coupler and the secondary coupler are disposed adjacent to each other and spaced apart by a gap (the secondary coupler comprising a plurality of secondary-side coils backed by a secondary-side core). The plurality of secondary-side coils are configured to induce into the secondary-side core a spatially-dependent magnetic field distribution that rotates around an axis orthogonal to the plurality of secondary-side magnetic coils. The secondary-side core has a variable thickness that varies in a plane orthogonal to the axis like a linear combination of instances of the spatially-dependent magnetic field distribution.

Clause 28: The polyphase wireless power transfer system according to any of the preceding system clauses, wherein the spatially-dependent magnetic field distribution is expressed as B(x, y; φ(t)), the thickness is expressed as t(x, y), and the spatially-dependent magnetic field distribution is expressed as

$$t ( x , y ) ∼ {\sum }_{k = 1}^{N} B ( x , y ; {φ}_{k} ) ,$$

where an instant phase is

$${φ}_{k} = \frac{( k - 1 ) π}{N} ,$$

k=1 . . . N is an integer, and N≥3.

Clause 29: The polyphase wireless power transfer system according to any of the preceding system clauses, wherein the secondary-side core comprises M layers each having a layer thickness Δt, that equals (tₘₐₓ−tₘᵢₙ)/M, where tₘₐₓ represents a maximum value of the layer thickness and tₘᵢₙ represents a minimum value of the layer thickness.

Clause 30: The polyphase wireless power transfer system according to any of the preceding system clauses, wherein the j^{th} layer of the secondary-side core has a respective contour that satisfies the condition

$${B}_{m i n} + j Δ B = {\sum }_{k = 1}^{N} B ( x , {y}_{j} ( x ) ; {φ}_{k} ) , where Δ B = \frac{{B}_{m ax} - {B}_{m i n}}{M} ,$$

Bₘₐₓ represents a maximum value of the spatially-dependent magnetic field distribution, Bₘᵢₙ represents a minimum value of the spatially-dependent magnetic field distribution.

Clause 31: The polyphase wireless power transfer system according to any of the preceding system clauses, wherein the linear combination of instances of the spatially-dependent magnetic field distribution is obtained by superimposing a plurality of contour plot maps showing magnetic flux density distributions at various phase angles for a magnetic core.

Clause 32: The polyphase wireless power transfer system according to any of the preceding system clauses, wherein the variable thickness of the secondary-side core increases in areas of relatively higher magnetic flux density and decreases in areas of relatively lower magnetic flux density.

Clause 33: The polyphase wireless power transfer system according to any of the preceding system clauses, wherein the plurality of secondary-side coils of the secondary coupler comprise polyphase coils arranged in a plurality of layers disposed on the secondary-side core.

Clause 34: The polyphase wireless power transfer system according to any of the preceding system clauses, wherein a number of instances of the spatially-dependent magnetic field distribution is equal to three, and the variable thickness t(x,y) of the secondary-side core varies as

$$t ( x , y ) ∼ [ B ( x , y ; \frac{π}{3} ) + B ( x , y ; \frac{2 π}{3} ) + B ( x , y ; π ) ] .$$

Clause 35: The polyphase wireless power transfer system according to any of the preceding system clauses, wherein the secondary-side core comprises a material with high magnetic permeability such as ferrite, nanocrystalline, or another type of magnetic material.

Clause 36: The polyphase wireless power transfer system according to any of the preceding system clauses, wherein the high-frequency AC power is in a range of 10-1000 kW.

Clause 37: The polyphase wireless power transfer system according to any of the preceding system clauses, wherein the high-frequency AC power is about 100 kW while it is possible to design the systems at other rated power levels.

Clause 38: The polyphase wireless power transfer system according to any of the preceding system clauses, wherein a fundamental frequency of the high-frequency AC power is in a range of 10-100 kHz.

Clause 39: The polyphase wireless power transfer system according to any of the preceding system clauses, wherein the fundamental frequency is about 85 kHz.

Clause 40: A method for providing a cooling system for a structure, comprising: cooling the structure using a thermal interface having a variable thickness, wherein the variable thickness increases in areas of relatively higher temperature and decreases in areas of relatively lower temperature.

Clause 41: The method according to clause 40, wherein the structure comprises an electronic device or a magnetic core structure.

Clause 42: A cooling system comprising a thermal interface having a variable thickness, wherein the variable thickness increases in areas of relatively higher temperature and decreases in areas of relatively lower temperature.

Clause 43: The cooling system of clause 42, wherein the thermal interface is configured to cool a structure.

Clause 44: The cooling system of claim 43, wherein the structure comprises an electronic device or a magnetic core structure.

The terms “processor” and “processing device” refer to a hardware component of an electronic device that is configured to execute programming instructions. Except where specifically stated otherwise, the singular terms “processor” and “processing device” are intended to include both single-processing device embodiments and embodiments in which multiple processing devices together or collectively perform a process.

The terms “memory,” “memory device,” “computer-readable medium,” “data store,” “data storage facility” and the like each refer to a non-transitory device on which computer-readable data, programming instructions or both are stored. Except where specifically stated otherwise, the terms “memory,” “memory device,” “computer-readable medium,” “data store,” “data storage facility” and the like are intended to include single device embodiments, embodiments in which multiple memory devices together or collectively store a set of data or instructions, as well as individual sectors within such devices. A computer program product is a memory device with programming instructions stored on it.

As used in this document, the singular form “a”, “an”, and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to”.

The described features, advantages and characteristics disclosed herein may be combined in any suitable manner. One skilled in the relevant art will recognize, in light of the description herein, that the disclosed systems and/or methods can be practiced without one or more of the specific features. In other instances, additional features and advantages may be recognized in certain scenarios that may not be present in all instances.

Although the systems and methods have been illustrated and described with respect to one or more implementations, equivalent alterations and modifications will occur to others skilled in the art upon the reading and understanding of this specification and the annexed drawings. In addition, while a particular feature may have been disclosed with respect to only one of several implementations, such feature may be combined with one or more other features of the other implementations as may be desired and advantageous for any given or particular application. Thus, the breadth and scope of the disclosure herein should not be limited by any of the above descriptions. Rather, the scope of the invention should be defined in accordance with the following claims and their equivalents.

What is claimed is:

1. A method for providing a magnetic field, comprising:
supplying AC power to an electromagnetic coil assembly comprising at least one coil and a magnetic core;
creating the magnetic field by the electromagnetic coil assembly; and
using the magnetic core to increase the magnetic field in the electromagnetic coil assembly, wherein the magnetic core has a variable thickness which increases in areas of relatively higher magnetic flux density and decreases in areas of relatively lower magnetic flux density.

2. The method according to claim 1, wherein the magnetic core is defined by a contoured surface that is a function of a linear combination of a plurality of instances of a spatially-dependent magnetic field distribution of the electromagnetic coil assembly.

3. The method according to claim 1, wherein the magnetic flux density is uniform or non-uniform across the magnetic core.

4. The method according to claim 1, wherein the magnetic core is fabricated based on a 3D model created by superimposing a plurality of contour plot maps showing magnetic flux density distributions at various phase angles.

5. The method according to claim 4, wherein the plurality of contour plot maps are created by performing simulation operations to generate a set of magnetic flux density distributions at various spatial coordinates for the magnetic core.

6. The method according to claim 4, wherein the magnetic core is fabricated using a 3D printing technique, an additive manufacturing technique, a substrative manufacturing technique, a stack or layering based manufacturing technique, and/or a sintering manufacturing technique.

7. The method according to claim 1, wherein the electromagnetic coil assembly and another electromagnetic coil assembly collectively comprise a wireless power transfer system.

8. The method according to claim 7, further comprising transferring power from the electromagnetic coil assembly to the another electromagnetic coil assembly by the magnetic field.

9. The method according to claim 8, further comprising using the transferred power to (re) charge a battery of an electronic device.

10. The method according to claim 9, wherein the electronic device comprises a vehicle.

11. The method according to claim 9, wherein the electromagnetic coil assembly resides off board the electronic device and the another electromagnetic coil assembly resides on board the electronic device.

12. The method according to claim 1, wherein the electromagnetic coil assembly comprises a polyphase coil.

13. The method according to claim 12, wherein the electromagnetic coil assembly comprises a plurality of coils that are configured to induce into the magnetic core a spatially-dependent magnetic field distribution that rotates around an axis orthogonal to the plurality of coils.

14. A system, comprising:
a power source configured to supply alternating current;
an electromagnetic coil assembly comprising at least one coil configured to create a magnetic field when the alternating current passes therethrough and a magnetic core configured to increase the magnetic coupling;
wherein the magnetic core has a variable thickness which increases in areas of relatively higher magnetic flux density and decreases in areas of relatively lower magnetic flux density.

15. The system according to claim 14, wherein the magnetic core is defined by a contoured surface that is a function of a linear combination of a plurality of instances of a spatially-dependent magnetic field distribution of the electromagnetic coil assembly.

16. The system according to claim 14, wherein the magnetic flux density is uniform or non-uniform across the magnetic core.

17. The system according to claim 14, wherein the magnetic core is fabricated based on a 3D model created by superimposing a plurality of contour plot maps showing magnetic flux density distributions at various phase angles.

18. The system according to claim 17, wherein the plurality of contour plot maps are created by performing simulation operations to generate a set of magnetic flux density distributions at various spatial coordinates for the magnetic core.

19. The system according to claim 17, wherein the magnetic core is fabricated using a 3D printing technique, an additive manufacturing technique, a substrative manufacturing technique, a stack or layering based manufacturing technique, and/or a sintering manufacturing technique.

20. The system according to claim 14, wherein the electromagnetic coil assembly and another electromagnetic coil assembly collectively comprise a wireless power transfer system.

21. The system according to claim 20, wherein power is transferred from the electromagnetic coil assembly to the another electromagnetic coil assembly by the magnetic field.

22. The system according to claim 21, wherein the transferred power is used to (re) charge a battery of an electronic device.

23. The system according to claim 22, wherein the electronic device comprises a vehicle.

24. The system according to claim 22, wherein the electromagnetic coil assembly resides off board the electronic device and the another electromagnetic coil assembly resides on board the electronic device.

25. The system according to claim 14, wherein the electromagnetic coil assembly comprises a polyphase coil.

26. The system according to claim 25, wherein the electromagnetic coil assembly comprises a plurality of coils that are configured to induce into the magnetic core a spatially-dependent magnetic field distribution that rotates around an axis orthogonal to the plurality of coils.

27. A polyphase wireless power transfer system for wirelessly providing high-frequency AC power to an electric vehicle, comprising:
an off-board transmitter comprising a primary coupler configured to wirelessly transmit the high-frequency AC power, the primary coupler comprising a plurality of primary-side coils backed by a primary-side core; and
an on-board receiver comprising a secondary coupler configured to receive the high-frequency AC power when the primary coupler and the secondary coupler are disposed adjacent to each other and spaced apart by a gap, the secondary coupler comprising a plurality of secondary-side coils backed by a secondary-side core;
wherein the plurality of secondary-side coils are configured to induce into the secondary-side core a spatially-dependent magnetic flux density distribution that rotates around an axis orthogonal to the plurality of secondary-side magnetic coils; and
wherein the secondary-side core has a variable thickness that varies in a plane orthogonal to the axis like a linear combination of instances of the spatially-dependent magnetic flux density distribution.

28. The polyphase wireless power transfer system according to claim 27, wherein the spatially-dependent magnetic field distribution is expressed as B(x, y; φ(t)), the thickness is expressed as t(x, y), and the spatially-dependent magnetic field distribution is expressed as
$$t ( x , y ) ∼ {\sum }_{k = 1}^{N} B ( x , y ; {φ}_{k} ) ,$$
where an instant phase is
$${φ}_{k} = \frac{( k - 1 ) π}{N} ,$$
k=1 . . . N is an integer, and N≥3.

29. The polyphase wireless power transfer system of claim 27, wherein the secondary-side core comprises M layers each having a layer thickness Δt, that equals (tₘₐₓ−tₘᵢₙ)/M, where tₘₐₓ represents a maximum value of the layer thickness and tₘᵢₙ represents a minimum value of the layer thickness.

30. The polyphase wireless power transfer system of claim 29, wherein the j^{th} layer of the secondary-side core has a respective contour that satisfies the condition
$${B}_{m i n} + j Δ B = {\sum }_{k = 1}^{N} B ( x , {y}_{j} ( x ) ; {φ}_{k} ) , where Δ B = \frac{{B}_{m ax} - {B}_{m i n}}{M} ,$$
Bₘₐₓ represents a maximum value of the spatially-dependent magnetic field distribution, Bₘᵢₙ represents a minimum value of the spatially-dependent magnetic field distribution.

31. The polyphase wireless power transfer system of claim 27, wherein the linear combination of instances of the spatially-dependent magnetic field distribution is obtained by superimposing a plurality of contour plot maps showing magnetic flux density distributions at various phase angles for a magnetic core.

32. The polyphase wireless power transfer system according to claim 27, wherein the variable thickness of the secondary-side core increases in areas of relatively higher magnetic flux density and decreases in areas of relatively lower magnetic flux density.

33. The polyphase wireless power transfer system according to claim 27, wherein the plurality of secondary-side coils of the secondary coupler comprise polyphase coils arranged in a plurality of layers disposed on the secondary-side core.

34. The polyphase wireless power transfer system according to claim 27, wherein a number of instances of the spatially-dependent magnetic field distribution is equal to three, and the variable thickness t(x,y) of the secondary-side core varies as
$$t ( x , y ) ∼ [ B ( x , y ; \frac{π}{3} ) + B ( x , y ; \frac{2 π}{3} ) + B ( x , y ; π ) ] .$$

35. The polyphase wireless power transfer system according to claim 27, wherein the secondary-side core comprises one of ferrite or nanocrystalline.

36. The polyphase wireless power transfer system according to claim 27, wherein the high-frequency AC power is in a range of 10-1000 kW.

37. The polyphase wireless power transfer system according to claim 27, wherein a fundamental frequency of the high-frequency AC power is in a range of 10 kHz-10 MHz.

38. A method for providing a cooling system for a structure, comprising:
cooling the structure using a thermal interface having a variable thickness, wherein the variable thickness increases in areas of relatively higher temperature and decreases in areas of relatively lower temperature.

39. The method according to claim 38, wherein the structure comprises an electronic device or a magnetic core structure.
